(19) United States
(12) Patent Application Publication
(10) Pub. No.: US 2026/0026014 A1
(43) Pub. Date: Jan. 22, 2026

(54) MEMORY DEVICE

(71) Applicant: SAMSUNG ELECTRONICS CO., LTD., Suwon-si (KR)

(72) Inventors: Hanmin Nam, Suwon-si (KR); Jeunghwan Park, Suwon-si (KR)

(21) Appl. No.: 19/025,511

(22) Filed: Jan. 16, 2025

(30) Foreign Application Priority Data
Jul. 17, 2024 (KR) 10-2024-0094406

(51) Int. Cl. H10B 80/00; H01L 23/00; H01L 25/00; H01L 25/065; H01L 25/18

(52) U.S. Cl. CPC H10B 80/00; H01L 24/06; H01L 24/08; H01L 24/80; H01L 25/0657; H01L 25/18; H01L 25/50; H01L 2224/06133; H01L 2224/08145; H01L 2224/80895; H01L 2224/80896; H01L 2924/1431; H01L 2924/14511

(57) ABSTRACT

A memory device includes a substrate, a gate line contact electrically connected to a gate line selected from among the gate lines, a conductive wiring structure connected to the gate line contact, and bonding pads arranged on the conductive wiring structure. The bonding pads include a first bonding pad, a second bonding pad, a third bonding pad apart from the first bonding pad in the first horizontal direction, and a fourth bonding pad apart from the first bonding pad in a second horizontal direction perpendicular to the first horizontal direction. The conductive wiring structure electrically connects the first bonding pad and the second bonding pad to the gate line contact, and the second bonding pad is arranged diagonally between the first horizontal direction and the second horizontal direction with respect to the first bonding pad.

### CROSS-REFERENCE TO RELATED APPLICATION(S)

This application claims priority under 35 U.S.C. § 119 to Korean Patent Application No. 10-2024-0094406, filed on Jul. 17, 2024, in the Korean Intellectual Property Office, the disclosure of which is incorporated by reference herein in its entirety.

### BACKGROUND

In electronic systems requiring data storage, there is an increasing demand for memory devices capable of storing high-capacity data. Accordingly, to increase data storage capacity of memory devices, a memory device that includes a vertical memory component in which memory cells are three-dimensionally arranged has been suggested.

### SUMMARY

The disclosure provides a memory device with a relatively improved integration level, the memory device including memory cells that are three-dimensionally arranged.

Technical problems to be solved by the disclosure are not limited to the above description, and other technical problems may be clearly understood by one of ordinary skill in the art from the descriptions provided hereinafter.

According to an aspect of some implementations, there is provided a memory device including a substrate, a gate stack including a plurality of gate lines stacked on the substrate in a vertical direction and extending in a first horizontal direction, a gate line contact electrically connected to a gate line selected from the plurality of gate lines, a conductive wiring structure electrically connected to the gate line contact, and a plurality of bonding pads arranged on the conductive wiring structure, wherein the plurality of bonding pads includes a first bonding pad, a second bonding pad, a third bonding pad spaced apart from the first bonding pad in the first horizontal direction, and a fourth bonding pad spaced apart from the first bonding pad in a second horizontal direction that is perpendicular to the first horizontal direction. The conductive wiring structure electrically connects the first bonding pad and the second bonding pad to the gate line contact, and the first bonding pad and the second bonding pad are arranged in a diagonal direction with respect to each other, the diagonal direction being defined between the first horizontal direction and the second horizontal direction.

According to another aspect of some implementations, there is provided a memory device including a first gate stack including a plurality of first gate lines that are stacked in a vertical direction and extend in a first horizontal direction, a lower cell array stack including a lower gate line contact electrically connected to a first gate line from the plurality of first gate lines, and a plurality of bonding pads arranged on the lower cell array stack, wherein the plurality of bonding pads include a first bonding pad, a second bonding pad, a third bonding pad spaced apart from the first bonding pad in the first horizontal direction, and a fourth bonding pad spaced apart from the first bonding pad in a second horizontal direction that is perpendicular to the first horizontal direction. The first bonding pad and the second bonding pad are electrically connected to the lower gate line contact. A first distance is defined from a center of the first bonding pad to a center of the second bonding pad, a second distance is defined from the center of the first bonding pad to a center of the third bonding pad, and a third distance is defined from the center of the first bonding pad to a center of the fourth bonding pad are defined, and the first distance is less than or equal to the second distance and the third distance.

According to another aspect of some implementations, there is provided a memory device including a substrate including a cell region and a connection region, a gate stack including a plurality of gate lines stacked on the substrate in a vertical direction and extending in a first horizontal direction, a vertical channel structure penetrating the gate stack in the cell region, a bit line electrically connected to the vertical channel structure, a gate line contact electrically connected to a gate line selected from the plurality of gate lines in the connection region, a conductive wiring structure electrically connected to the gate line contact, and a plurality of bonding pads arranged on the conductive wiring structure, wherein the plurality of bonding pads include a first bonding pad electrically connected to the gate line contact, a second bonding pad electrically connected to the gate line contact, a third bonding pad spaced apart from the first bonding pad in the first horizontal direction, and a fourth bonding pad spaced apart from the first bonding pad in a second horizontal direction that is perpendicular to the first horizontal direction, a first distance is defined from a center of the first bonding pad to a center of the second bonding pad, a second distance is defined from the center of the first bonding pad to a center of the third bonding pad, and a third distance is defined from the center of the first bonding pad to a center of the fourth bonding pad, and the first distance is less than or equal to the second distance and the third distance.

### BRIEF DESCRIPTION OF THE DRAWINGS

Implementations will be more clearly understood from the following detailed description taken in conjunction with the accompanying drawings in which:

FIG. 1 is a block diagram of a memory device according to some implementations;

FIG. 2 is a circuit diagram of a memory block according to some implementations;

FIG. 3 is a schematic plan view of a memory device according to some implementations;

FIG. 4 is a cross-sectional view of the memory device of FIG. 3, taken along a line A-A′ of FIG. 3;

FIG. 5 is an enlarged view showing region “EXTa” of FIG. 3;

FIG. 6 is a cross-sectional view of the memory device of FIG. 3, taken along a line B-B′ of FIG. 5;

FIGS. 7A and 7B respectively show some of the components shown in FIG. 5;

FIG. 8 is a plan view of a memory device according to some implementations;

FIG. 9 is a plan view of a memory device according to some implementations;

FIG. 10 is a plan view of a memory device according to some implementations;

FIG. 11 is a cross-sectional view of the memory device of FIG. 10, taken along a line C-C′ of FIG. 10;

FIGS. 12 and 13 are cross-sectional views of a memory device according to some implementations;

FIGS. 14 and 15 are cross-sectional views of a memory device according to some implementations;

FIG. 16 is a plan view of a memory device according to some implementations;

FIG. 17 is a plan view of a memory device according to some implementations;

FIGS. 18 and 21 are cross-sectional views showing a method of manufacturing a memory device in a process order, according to some implementations;

FIG. 22 schematically shows a data storage system including a memory device, according to some implementations;

FIG. 23 is a schematic perspective view of a data storage system including a semiconductor device, according to some implementations; and

FIG. 24 is a schematic cross-sectional view of semiconductor packages according to some implementations.

### DETAILED DESCRIPTION

Hereinafter, one or more implementations will be described in detail with reference to the attached drawings. Like reference numerals in the drawings denote like elements, and repeated descriptions thereof will be omitted.

In the present specification, a horizontal direction may include a first horizontal direction (e.g., X direction) and a second horizontal direction (e.g., Y direction). A direction crossing the first horizontal direction (e.g., X direction) and the second horizontal direction (e.g., Y direction) may be referred to as a vertical direction (e.g., Z direction). In the present specification, the vertical level may be referred to as a height level of any structure along the vertical direction (e.g., Z direction).

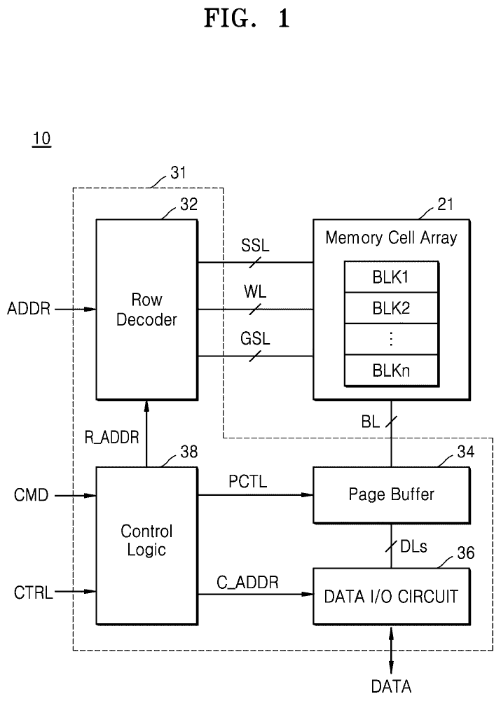

FIG. 1 is a block diagram of a memory device 10 according to some implementations.

Referring to FIG. 1, the memory device 10 may include a memory cell array 21 and a peripheral circuit 31. The memory cell array 21 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 31 through a bit line BL, a word line WL, a string selection line SSL, and a ground selection line GSL.

The peripheral circuit 31 may include a row decoder 32, a page buffer 34, a data input/output circuit 36, a control logic 38, and a common source line driver. The peripheral circuit 31 may further include an input/output interface, a column logic, a voltage generator, a pre-decoder, a temperature sensor, a command decoder, an address decoder, an amplifying circuit, and the like.

The memory cell array 21 may be connected to the page buffer 34 through the bit line BL and to the row decoder 32 through the word line WL, the string selection line SSL, and the ground selection line GSL. In the memory cell array 21, the memory cells in each of the memory cell blocks BLK1, BLK2, . . . , and BLKn may be flash memory cells. The memory cell array 21 may include a three-dimensional memory cell array. The three-dimensional memory cell array may include a plurality of NAND strings, and each NAND string may include a plurality of memory cells connected to a plurality of word lines WL that are vertically stacked on a substrate.

The peripheral circuit 31 may receive an address ADDR, a command CMD, and a control signal CTRL from the outside of the memory device 10 and may receive/transmit data DATA from/to a device outside the memory device 10.

The row decoder 32 may select at least one of the memory cell blocks BLK1, BLK2, . . . , and BLKn in response to an external address ADDR and select a word line WL, a string selection line SSL, and a ground selection line GSL of the selected memory cell block. The row decoder 32 may transmit a voltage used to perform a memory operation to the word line WL of the selected memory cell block.

The page buffer 34 may be connected to the memory cell array 21 through the bit line BL. The page buffer 34 may function as a write driver during a program operation and thus may apply, to the bit line BL, a voltage according to data DATA to be stored in the memory cell array 21, and the page buffer 34 may function as a sense amplifier during a read operation and thus may detect data DATA stored in the memory cell array 21. The page buffer 34 may operate according to a control signal PCTL provided from the control logic 38.

The data input/output circuit 36 may be connected to the page buffer 34 through data lines DLs. During the program operation, the data input/output circuit 36 may receive data DATA from a memory controller and may provide program data DATA to the page buffer 34 based on a column address C_ADDR provided from the control logic 38. During the read operation, the data input/output circuit 36 may provide the memory controller with the read data DATA that is stored in the page buffer 34, based on the column address C_ADDR provided from the control logic 38.

The data input/output circuit 36 may transmit an input address or command to the control logic 38 or the row decoder 32. The peripheral circuit 31 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and a column address C_ADDR to the data input/output circuit 36. The control logic 38 may generate a variety of internal control signals used in the memory device 10, in response to the control signal CTRL. For example, the control logic 38 may adjust a voltage level provided to the word line WL and the bit line BL during a memory operation, such as a program operation or an crase operation.

The common source line driver may be connected to the memory cell array 21 through a common source line CSL. The common source line driver may apply a common source voltage (e.g., a power voltage) or a ground voltage to the common source line CSL, according to the control by the control logic 38.

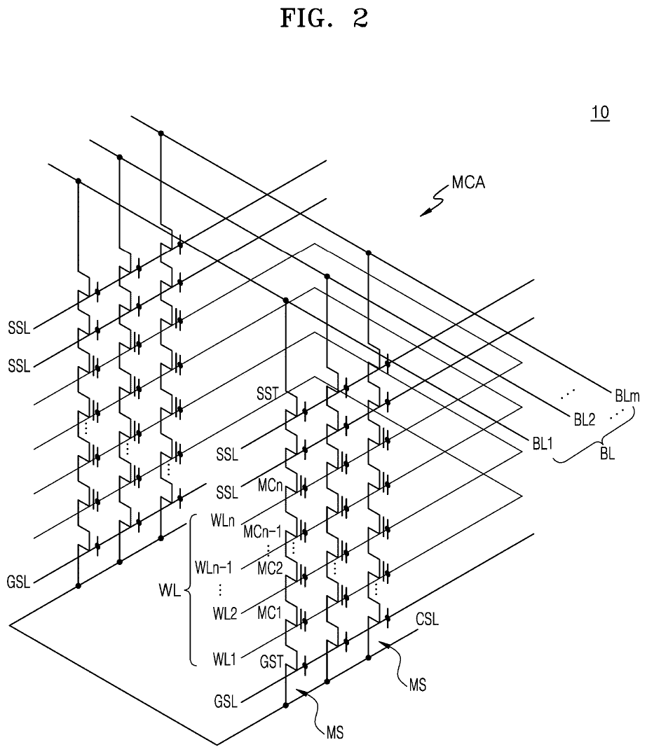

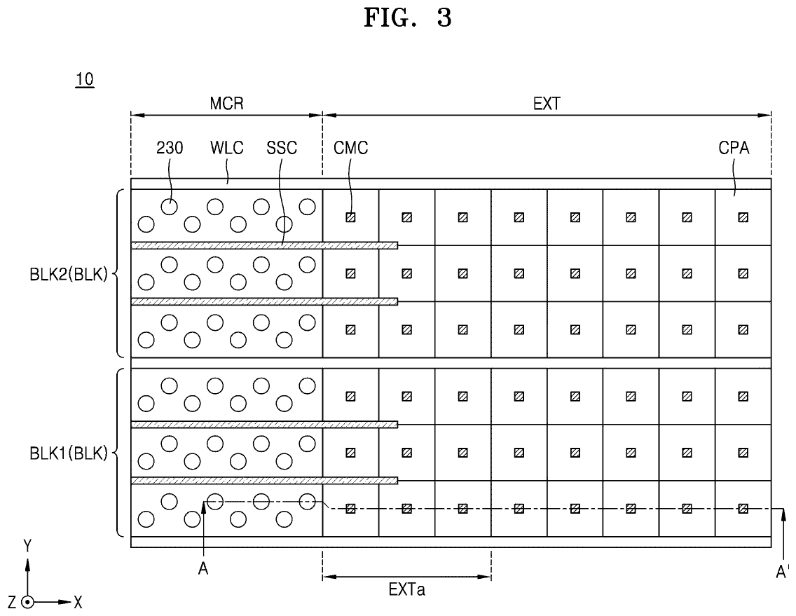

FIG. 2 is a circuit diagram of a memory block according to some implementations.

Referring to FIG. 2, a memory cell array MCA may include a plurality of memory cell strings MS. The memory cell array MCA may include a plurality of bit lines BL (BL1, BL2, . . . , and BLm), a plurality of word lines WL (WL1, WL2, . . . . WLn-1, and WLn), at least one string selection line SSL, at least one ground selection line GSL, and a common source line CSL. The memory cell strings MS may be formed between the bit lines BL (BL: BL1, BL2, . . . , and BLm) and the common source line CSL. FIG. 2 shows an example in which each memory cell string MS includes two string selection lines SSL, but one or more implementations are not limited thereto. For example, each memory cell string MS may include one string selection line SSL.

Each memory cell string MS may include a string selection transistor SST, a ground selection transistor GST, and a plurality of memory cell transistors MC1, MC2, . . . , MCn-1, and MCn. A drain area of the string selection transistor SST may be connected to the bit line BL (BL: BL1, BL2, . . . , and BLm), and a source area of the ground selection transistor GST may be connected to the common source line CSL. The common source line CSL may be an area where source areas of the ground selection transistors GST are commonly connected.

The string selection transistor SST may be connected to the string selection line SSL, and the ground selection transistor GST may be connected to the ground selection line GSL. The memory cell transistors MC1, MC2, . . . , MCn-1, and MCn may be connected to the word lines WL (WL: WL1, WL2, . . . , WLn-1, and WLn), respectively.

FIGS. 3, 4, 5, and 6 are diagrams of the memory device 10 according to some implementations.

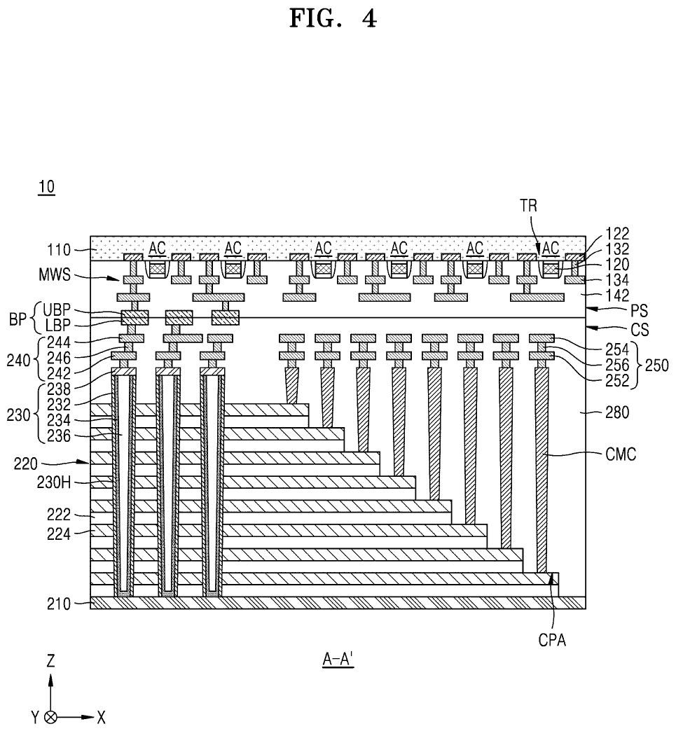

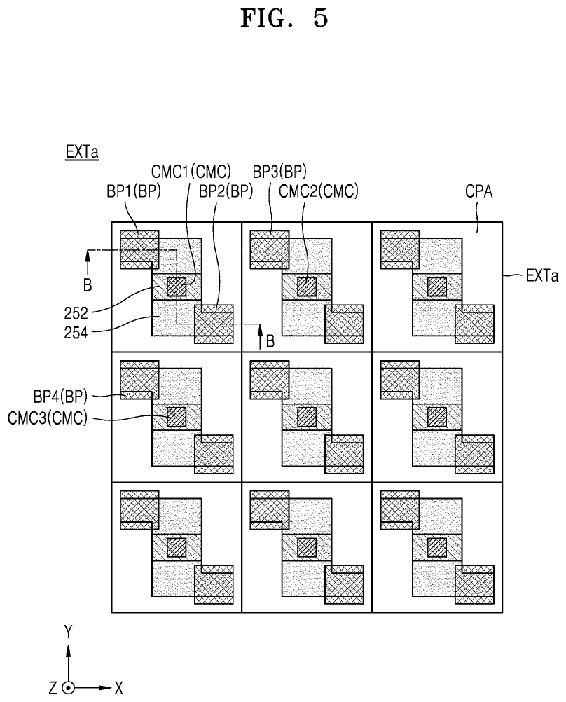

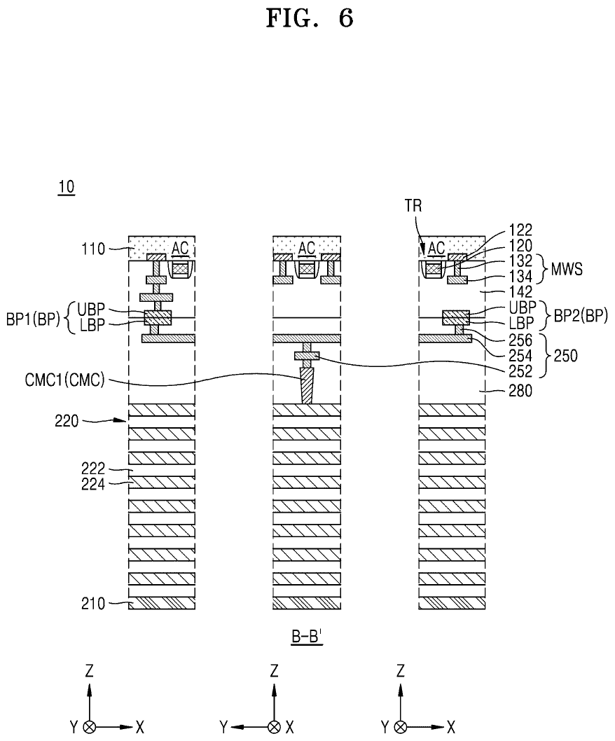

In detail, FIG. 3 is a schematic plan view of the memory device 10 according to some implementations. FIG. 5 is an enlarged view showing region “EXTa” of FIG. 3; FIG. 4 is a cross-sectional view of the memory device 10 of FIG. 3, taken along a line A-A′ of FIG. 3. FIG. 6 is a cross-sectional view of the memory device 10 of FIG. 3, taken along a line B-B′ of FIG. 5.

Referring to FIGS. 3, 4, and 6, the memory device 10 may include a cell array stack CS and a peripheral circuit stack PS arranged on the cell array stack CS to overlap the same in the vertical direction (the Z direction). The cell array stack CS may include the memory cell array 21 described with reference to FIG. 1, and the peripheral circuit stack PS may include the peripheral circuit 31 described with reference to FIG. 1.

Referring to FIG. 4, the peripheral circuit stack PS may include a circuit substrate 110, a plurality of circuits arranged on the circuit substrate 110, and a multilayer wiring structure MWS for interconnecting the circuits or connecting the circuits to components included in the cell array stacks CS.

In the peripheral circuit stack PS, the circuit substrate 110 may include a semiconductor substrate. For example, the circuit substrate 110 may include silicon (Si), germanium (Ge), or SiGe. Active areas AC may be defined in the circuit substrate 110 by a device isolation layer. Above the active areas AC, a plurality of transistors TR forming the circuits may be formed. Each of the transistors TR may include a gate 120 and a plurality of ion implantation areas 122 formed on both sides of the gate 120 in the active area AC. Each ion implantation area 122 may form a source area or a drain area of the transistor TR.

The circuits included in the peripheral circuit stack PS may include various circuits included in the peripheral circuit 31 described with reference to FIG. 1. In implementations, the circuits included in the peripheral circuit stack PS may include the row decoder 32, the page buffer 34, the data input/output circuit 36, and the control logic 38 shown in FIG. 1.

The multilayer wiring structure MWS included in the peripheral circuit stack PS may include a plurality of peripheral circuit contacts 132 and a plurality of circuit wiring layers 134. At least some of the circuit wiring layers 134 may be configured to be electrically connected to the transistors TR. The peripheral circuit contacts 132 may be configured to interconnect the transistors TR to selected ones of the circuit wiring layers 134.

A plurality of conductive components included in the cell array stack CS may each be configured to be connected to at least one circuit selected from among the circuits through the multilayer wiring structure MWS included in the peripheral circuit stack PS. Although FIGS. 4 and 6 show that the multilayer wiring structure MWS includes two layer circuit wiring layers 134 along the vertical direction (the Z direction), one or more implementations are not limited to what is shown in FIGS. 4 and 6. For example, the multilayer wiring structure MWS may include at least three or more circuit wiring layers 218.

The peripheral circuit contacts 132 and the circuit wiring layers 134 may each include metal, conductive metal nitride, metal silicide, or a combination thereof. For example, the peripheral circuit contacts 132 and the circuit wiring layers 134 may each include a conductive material, such as tungsten, molybdenum, titanium, cobalt, tantalum, nickel, tungsten silicide, titanium silicide, cobalt silicide, tantalum silicide, or nickel silicide.

The transistors TR and the multilayer wiring structure MWS included in the peripheral circuit stack PS may be covered by a peripheral circuit insulating layer 142. The peripheral circuit insulating layer 142 may include silicon oxide, SiON, SiOCN, or the like.

Referring to FIGS. 3 and 4 together, the cell array stack CS may include a plurality of memory cell blocks BLK. The memory cell blocks BLK may correspond to the memory cell blocks BLK1, BLK2, . . . , and BLKn described with reference to FIG. 1. Each memory cell block BLK may include a plurality of memory cells that are three-dimensionally arranged. Each memory cell block BLK may have a planar shape extending along the first horizontal direction (the X direction) in plan view (the X-Y plane in FIG. 3). Each memory cell block BLK may include a cell region MCR and a connection region EXT arranged on a side of the cell region MCR in the first horizontal direction (the X direction).

The cell region MCR may be the region where the vertical channel structures 230 are arranged and may correspond to the memory cell array 21 of FIG. 1, and the connection region EXT may be the region where the gate lines 224 extend to different lengths and may be configured to electrically connect the memory cell array of FIG. 1 to the peripheral circuit 31 of FIG. 1. The connection region EXT may include a plurality of contact regions CPA. On any one contact region CPA selected from among the contact regions CPA, one gate line contact CMC may be arranged.

The cell array stack CS may include the substrate 210 including the cell region MCR and the connection region EXT, the interlayer insulating layers 222 and the gate lines 224 that are alternately stacked on the substrate 210, the vertical channel structures 230 that extend by penetrating the interlayer insulating layers 222 and the gate lines 224, the gate line contacts CMC that are electrically connected to the gate lines 224 respectively, the conductive wiring structure 240 that electrically connects between the vertical channel structures 230 and the bonding pads BP, the conductive wiring structure 250 that electrically connects between the gate line contacts CMC and the bonding pads BP, and the cell insulating layer 280.

The substrate 210 may include a semiconductor material, for example, a group IV semiconductor, a group III-V compound semiconductor, or a group II-VI compound semiconductor. For example, the group IV semiconductor may include Si, Ge, or SiGe. For example, the substrate 210 may be provided as a single crystal layer or an epitaxial layer.

The interlayer insulating layers 222 and the gate lines 224 may extend in parallel with each other along the horizontal direction (the X direction and the Y direction in FIG. 6) and overlap each other in the vertical direction (the Z direction). In this case, the interlayer insulating layer 222 may be located under the lowermost gate line 224 among the gate lines 224. The gate lines 224 may form a gate stack 220.

Referring to FIGS. 3 and 4 together, in some implementations, the gate lines 224 may be stacked apart from each other in the vertical direction (the Z direction) and extend from the cell region MCR to the connection region EXT to different lengths in the first horizontal direction (the X direction), thus forming a stepped structure. In some implementations, as shown in FIG. 4, end portions of respective gate lines 224 may form a step difference and generate a stepped shape in the first horizontal direction (the X direction). In some implementations, the end portions of respective gate lines 224 may form a step difference and generate a stepped shape in the second horizontal direction (the Y direction). Because of the above stepped shape, an upper surface of each gate line 224 may be partially exposed. The exposed portion of the upper surface of each gate line 224 may provide the contact region CPA.

In some implementations, the gate lines 224 may be stacked apart from each other in the vertical direction (the Z direction) and may extend to the same length from the cell region MCR to the connection region EXT in the first horizontal direction (the X direction). Implementations are not limited to the gate lines 224 extending to different lengths in the first horizontal direction (the X direction) and forming steps, as shown in FIG. 4.

Each interlayer insulating layer 222 may include silicon oxide. Each gate line 224 may include metal, metal silicide, a semiconductor doped with impurities, or a combination thereof. For example, each gate line 224 may include metal such as tungsten, nickel, cobalt, or tantalum, metal silicide such as tungsten silicide, nickel silicide, cobalt silicide, or tantalum silicide, doped polysilicon, or a combination thereof.

Referring to FIG. 3, a plurality of word line cut structures WLC, each extending from the cell region MCR to the connection region EXT in the first horizontal direction (the X direction), may be arranged between each pair of memory cell blocks BLK. The word line cut structures WLC may be arranged apart from each other in the second horizontal direction (the Y direction). Each word line cut structure WLC may penetrate the gate stack (220 of FIG. 4) in the vertical direction (the Z direction). The memory cell blocks BLK may be arranged between each pair of word line cut structures WLC. Each word line cut structure WLC may be placed on both sides of each memory cell block BLK in the second horizontal direction (the Y direction) to define the width of each memory cell block BLK in the second horizontal direction (the Y direction).

Each word line cut structure WLC may include an insulating structure. In implementations, the insulating structure may include silicon oxide, silicon nitride, silicon oxynitride, or a low-k dielectric material. For example, the insulating structure may include a silicon oxide layer, a silicon nitride layer, an SiON layer, an SiOCN layer, an SiCN layer, or a combination thereof. In some implementations, at least a portion of the insulating structure may include an air gap. The term “air” used in the present specification may refer to the atmosphere or other gases present during the manufacturing processes.

In addition, a plurality of string isolation cut structures SSC may be arranged between each pair of the word line cut structure WLC. The string isolation cut structures SSC may separate at least one gate line 224 into two gate lines within one memory cell block BLK. For example, the string isolation cut structures SSC may separate the uppermost gate line among at least one gate line (224 of FIG. 4) in the second horizontal direction (the Y direction). The number of gate lines 224 separated by the string isolation cut structures SSC may vary according to some implementations. The string isolation cut structures SSC may extend in the cell region MCR and the connection region EXT in the first horizontal direction (the X direction) and may be spaced apart from each other in the second horizontal direction (the Y direction).

The string isolation cut structures SSC may include insulating layers. In implementations, the string isolation cut structures SSC may each include an insulating layer including an oxide layer, a nitride layer, or a combination thereof.

In some implementations, the cell array stack CS may include a common source line layer located between the substrate 210 and the gate stack 220. The common source line layer may perform the function of the common source line CSL described with reference to FIG. 1 and may correspond to the common source line CSL shown in FIG. 2. In other words, the common source line layer may function as a source area where currents are supplied to vertical memory cells included in the cell array stack CS. In some implementations, the cell array stack CS may include a common source line layer formed in the substrate 210. The common source line layer may include a doped polysilicon layer, a metal layer, or a combination thereof, and the metal layer may include tungsten (W); however, one or more implementations are not limited thereto.

Referring to FIGS. 3 and 4, a plurality of vertical channel structures 230 may be arranged in the cell region MCR of the substrate 210. The vertical channel structures 230 may extend by penetrating the interlayer insulating layers 222 and the gate lines 224 in the vertical direction (the Z direction). The vertical channel structures 230 may be spaced apart from each other at certain intervals in the first horizontal direction (the X direction) and the second horizontal direction (the Y direction).

Each vertical channel structure 230 may include a gate dielectric layer 232, a channel layer 234, a buried insulating layer 236, and a capping layer 238. Each vertical channel structure 230 may be a structure formed in a channel hole 230H that penetrates the interlayer insulating layers 222 and the gate lines 224. In some implementations, the gate dielectric layer 232 may conformally cover the sidewalls of the channel hole 230H, the channel layer 234 may conformally cover the sidewalls of the gate dielectric layer 232, and the buried insulating layer 236 may fill the remaining space in the channel hole 230H above the channel layer 234. In this case, the channel layer 234 may have a cylinder shape. The capping layer 238 may be arranged above the gate dielectric layer 232, the channel layer 234, and the buried insulating layer 236. In some implementations, the buried insulating layer 236 may be omitted, and the channel layer 234 may have a pillar shape filling the remaining space in the channel hole 230H above the gate dielectric layer 232.

In implementations, the gate dielectric layer 232 may include a tunneling dielectric layer, a charge storage layer, and a blocking dielectric layer that are sequentially formed. The tunneling dielectric layer may include silicon oxide, hafnium oxide, aluminum oxide, zirconium oxide, tantalum oxide, or the like. The charge storage layer may be a region in which electrons passing through the tunneling dielectric layer from the channel layer 234 may be stored, and may include silicon nitride, boron nitride, silicon boron nitride, or polysilicon doped with impurities. The blocking dielectric layer may include silicon oxide, silicon nitride, or metal oxide having greater permittivity than that of silicon oxide. The above metal oxide may include hafnium oxide, aluminum oxide, zirconium oxide, tantalum oxide, or a combination thereof. In implementations, the channel layer 234 may include polysilicon doped with impurities or polysilicon not being doped with impurities. In implementations, the buried insulating layer 236 may include silicon oxide, silicon nitride, silicon oxynitride, or a combination thereof. In implementations, the capping layer 238 may include a doped polysilicon layer.

The vertical channel structures 230 may be electrically connected to the conductive wiring structure 240 and a common source line layer. An end portion of each vertical channel structure 230 may contact the conductive wiring structure 240, and the other end portion of each vertical channel structure 230 may contact the common source line layer. The conductive wiring structure 240 may include a first wire layer 242, a second wire layer 244, and a conductive plug 246 that are located at different vertical levels. It is illustrated that the conductive wiring structure 240 includes two layers, that is, the first wire layer 242 and the second wire layer 244, but it is merely an example. The conductive wiring structure 240 may include a plurality of wire layers located at different vertical levels. The conductive plugs 246 may be respectively arranged between the first wire layer 242 and the second wire layer 244, between the first wire layer 242 and the vertical channel structures 230, and between the second wire layer 244 and the bonding pad BP. In some implementations, the first wire layer 242 may be a bit line (BL of FIGS. 1 and 2). The surface of the conductive wiring structure 240 may be covered by the cell insulating layer 280.

Referring to FIGS. 3 to 6 together, the gate line contacts CMC may be arranged in the connection region EXT of the substrate 210. The gate line contacts CMC may be arranged apart from each other in the first horizontal direction (the X direction) and the second horizontal direction (the Y direction). In this case, the gate line contacts CMC may respectively have different vertical lengths and may be physically and electrically connected to the gate lines 224 in the contact region CPA. For example, the gate line contacts CMC may have vertical lengths that decrease away from the cell region MCR in the first horizontal direction (the X direction), and the vertical level of the lower surface of the gate line contact CMC may increase away from the cell region MCR in the first horizontal direction (the X direction).

In some implementations, each gate line contact CMC may include a conductive material layer and an insulating spacer that surrounds the sidewall of the conductive material layer. The conductive material layer may include tungsten, titanium, tantalum, copper, aluminum, titanium nitride, tantalum nitride, tungsten nitride, or a combination thereof, but one or more implementations are not limited thereto. The insulating spacer may include oxide or silicon oxide.

Each gate line contact CMC may be electrically connected to the conductive wiring structure 250 and to any one of the gate lines 224 selected from among the gate lines 224. An end portion of each gate line contact CMC may contact the conductive wiring structure 250, and the other end portion thereof may contact any one of the gate lines 224 selected from among the gate lines 224.

The conductive wiring structure 250 may include a first wire layer 252, a second wire layer 254, and a conductive plug 256 that are located at different vertical levels. It is illustrated that the conductive wiring structure 250 includes two layers, that is, the first wire layer 252 and the second wire layer 254, but it is merely an example. The conductive wiring structure 250 may include a plurality of wire layers located at different vertical levels. The conductive plugs 256 may be respectively arranged between the first wire layer 252 and the second wire layer 254, between the first wire layer 252 and the gate line contact CMC, and between the second wire layer 254 and the bonding pad BP.

As shown in FIG. 5, the first wire layer 252 may overlap at least a portion of the gate line contact CMC in the vertical direction (the Z direction). A portion of the second wire layer 254 may overlap at least a portion of the first wire layer 252 in the vertical direction (the Z direction), and a portion of the second wire layer 254 may overlap a least a portion of the bonding pads BP (e.g., a first bonding pad BP1 and a second bonding pad BP2) in the vertical direction (the Z direction).

In some implementations, the first wire layer 252 may have an island shape, and the second wire layer 254 may have a line shape extending in a zigzag form to overlap, in the vertical direction (the Z direction), at least a portion of the first wire layer 252 and at least a portion of the bonding pads BP (e.g., the first bonding pad BP1 and the second bonding pad BP2). However, this is only an example, and the first wire layer 252 and the second wire layer 254 may have various shapes to electrically connect the bonding pads BP (e.g., the first bonding pad BP1 and the second bonding pad BP2) to the gate line contacts CMC.

The cell array stack CS may be attached to the peripheral circuit stack PS through the bonding pads BP. Each bonding pad BP may include a lower bonding metal pad LBP included in a pair of cell array stacks CS and an upper bonding metal pad UBP included in the peripheral circuit stack PS. The lower bonding metal pad LBP may be combined integrally with the upper bonding metal pad UBP. The bonding pads BP may each include copper, aluminum, or tungsten, but one or more implementations are not limited thereto.

As shown in FIG. 5, the bonding pads BP may include the first bonding pad BP1, the second bonding pad BP2, a third bonding pad BP3 spaced apart from the first bonding pad BP1 in the first horizontal direction (the X direction), and a fourth bonding pad BP4 spaced apart from the first bonding pad BP1 in the second horizontal direction (the Y direction). The first bonding pad BP1 and the second bonding pad BP2 may be arranged in a diagonal direction between the first horizontal direction (the X direction) and the second horizontal direction (the Y direction). In some implementations, the second bonding pad BP2 may be spaced apart from the first bonding pad BP1 in the diagonal direction.

The gate line contacts CMC may include a first gate line contact CMC1, a second gate line contact CMC2 spaced apart from the first gate line contact CMC1 in the first horizontal direction (the X direction), and a third gate line contact CMC3 spaced apart from the second gate line contact CMC2 in the second horizontal direction (the Y direction).

A pair of bonding pads BP, which are adjacent to each other in the diagonal direction among the bonding pads BP, may be electrically connected to the same gate line contact CMC. For example, the first bonding pad BP1 and the second bonding pad BP2 may be electrically connected to the first gate line contact CMC1. The third bonding pad BP3 may be electrically connected to the second gate line contact CMC2 that is different from the first gate line contact CMC1, and the fourth bonding pad BP4 may be electrically connected to the third gate line contact CMC3 that is different from the first gate line contact CMC1.

A pair of bonding pads BP, which are adjacent to each other in the diagonal direction among the bonding pads BP, may be electrically connected to any one of the gate lines 224 selected from among the gate lines 224, that is, the same gate line 224, through the gate line contact CMC. As shown in FIG. 6, for example, the first bonding pad BP1 and the second bonding pad BP2 may be electrically connected to the uppermost gate line 224 through the first gate line contact CMC1.

In detail, the first bonding pad BP1 may be electrically connected to the second wire layer 254 through the conductive plug 256 under the first bonding pad BP1, and the second bonding pad BP2 may be electrically connected to the second wire layer 254 through the conductive plug 256 under the second bonding pad BP2, to the first wire layer 252 through the conductive plug 256 under the second bonding pad BP2, and to the first gate line contact CMC through the conductive plug 256 under the first wire layer 252.

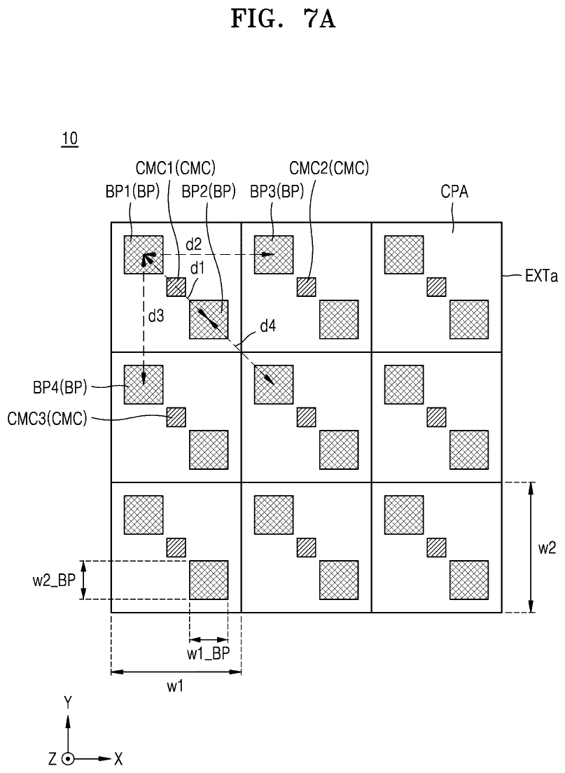

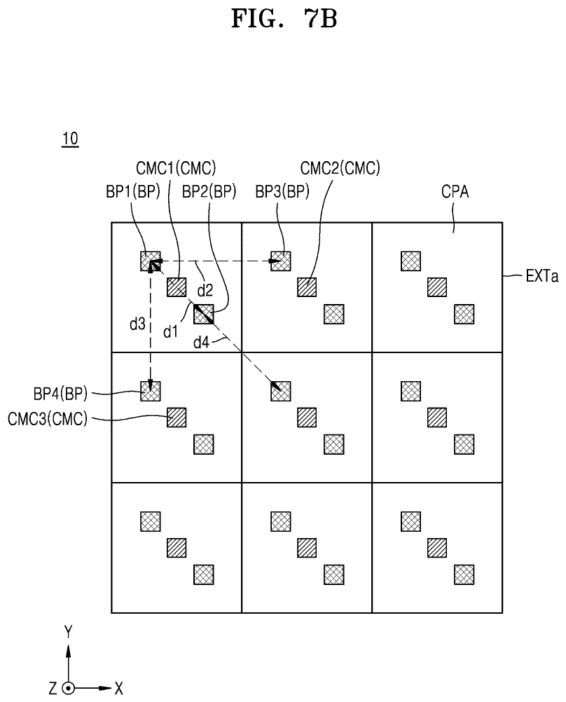

FIGS. 7A and 7B respectively show some of the components shown in FIG. 5.

Referring to FIG. 7A, in implementations, the bonding pads BP may have first pad widths w1_BP in the first horizontal direction (the X direction) and second pad widths w2_BP in the second horizontal direction (the Y direction).

In some implementations, the first pad width w1_BP may be less than the first width w1 of the contact region CPA in the first horizontal direction (the X direction), and the second pad width w2_BP may be less than the second width w2 in the second horizontal direction (the Y direction). In some implementations, a pair of bonding pads BP, which are adjacent to each other in a diagonal direction among the bonding pads BP, may be spaced apart from each other, the first pad width w1_BP of the bonding pads BP may be less than half of the first width w1, and the second pad width w2_BP may be less than half of the second width w2.

For example, the first pad width w1_BP and the second pad width w2_BP of the bonding pads BP may each be in a range from about 0.01 micrometers to about 1.4 micrometers and preferably in a range from about 0.87 micrometers to about 1.2 micrometers. In some implementations, the first pad width w1_BP may be the same as the second pad width w2_BP. In some implementations, the first pad width w1_BP may be different from the second pad width w2_BP.

In some implementations, each bonding pad BP may have the first pad width w1_BP and the second pad width w2_BP that are the same as each other. In some implementations, the bonding pads BP may have the first pad width w1_BP and the second pad width w2_BP that are different from each other. It is illustrated that each bonding pad BP has a square shape, but the shape of the bonding pad BP is not limited thereto. The shape may be in various forms, for example, a rhombus, a circle, and an oval.

Referring to FIGS. 7A and 7B, the distance from the center of the first bonding pad BP1 to the center of the second bonding pad BP2 may be defined as a first distance d1, the distance from the center of the first bonding pad BP1 to the center of the third bonding pad BP3 may be defined as a second distance d2, and the distance from the center of the first bonding pad BP1 to the center of the fourth bonding pad BP4 may be defined as a third distance d3. In some implementations, the first distance d1 may be the same as or less than the second distance d2 and the third distance d3.

For example, the first distance d1 may be in a range from about 0.8 micrometers to about 1.0 micrometer, the second distance d2 may be in a range from about 1.0 micrometer to about 1.4 micrometers, and the third distance d3 may be in a range from about 1.2 micrometers to about 1.6 micrometers.

In some implementations, the distance from the center of the first bonding pad BP1 or the second bonding pad BP2 in any one of the contact regions CPA selected from among the contact regions CPA to the center of the bonding pad BP, which is located in a contact region CPA diagonally adjacent to the selected contact region CPA and is adjacent to the first bonding pad BP1 or the second bonding pad BP2, may be defined as the fourth distance d4. As shown in FIG. 7A, for example, the distance from the center of the second bonding pad BP2 to the center of the bonding pad BP, which is adjacent to the second bonding pad BP2 in the diagonal direction but is electrically connected to another gate line contact CMC different from that electrically connected to the second bonding pad BP2, may be the fourth distance d4. The fourth distance d4 may be in a range from about 0.8 micrometers to about 1.0 micrometer. In some implementations, the fourth distance d4 may be the same as the first distance d1. In some implementations, the fourth distance d4 may be greater than the first distance d1. FIG. 7A illustrates that the fourth distance d4 is the same as the first distance d1, and FIG. 7B illustrates that the fourth distance d4 is greater than the first distance d1.

According to one or more implementations, the memory device 10 includes a plurality of bonding pads BP connected to one gate line contact CMC to prevent interruptions in current flow due to a bad connection between the gate line contact CMC and the bonding pads BP. In the memory device 10, two bonding pads BP are electrically connected to a single gate line contact CMC, but at least three bonding pads BP may be electrically connected to a single gate line contact CMC.

In addition, compared to a memory device with two bonding pads that are adjacent to each other in the first horizontal direction (the X direction) or the second horizontal direction (the Y direction) in the Comparative Example, the memory device 10 according to some implementations has two bonding pads BP that are diagonally adjacent to each other, and thus, the level of integration may increase. Moreover, the area overhead, where the area required to form the bonding pads BP and the conductive wiring structure 250 is greater than the connection area EXT, may be reduced.

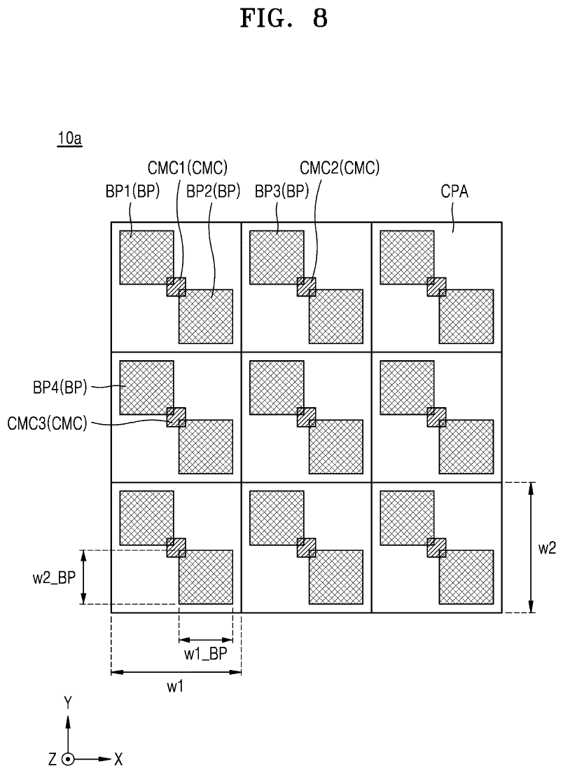

FIG. 8 is a plan view of a memory device 10a according to some implementations.

FIG. 8 shows a region corresponding to the region “EXTa” of FIG. 3.

Referring to FIG. 8, because the memory device 10a may be substantially similar to the memory device 10 described above, the difference therebetween is specifically described hereinafter.

The memory device 10a may include a plurality of bonding pads BP. The bonding pads BP may include the first bonding pad BP1, the second bonding pad BP2, the third bonding pad BP3 spaced apart from the first bonding pad BP1 in the first horizontal direction (the X direction), and the fourth bonding pad BP4 spaced apart from the first bonding pad BP1 in the second horizontal direction (the Y direction). The first bonding pad BP1 and the second bonding pad BP2 may be diagonally arranged between the first horizontal direction (the X direction) and the second horizontal direction (the Y direction). In some implementations, the second bonding pad BP2 may be diagonally spaced apart from the first bonding pad BP1.

In some implementations, among the bonding pads BP that are diagonally adjacent to each other, at least one bonding pad BP may overlap a portion of the gate line contact CMC in the vertical direction (the Z direction). For example, the first bonding pad BP1 and/or the second bonding pad BP2 among the bonding pads BP may overlap a portion of the first gate line contact CMC1 in the vertical direction (the Z direction).

In some implementations, among the bonding pads BP that are diagonally adjacent to each other, any one selected bonding pad BP may fully overlap the gate line contact CMC in the vertical direction (the Z direction). For example, the first bonding pad BP1 and/or the second bonding pad BP2 may overlap the entire first gate line contact CMC1 in the vertical direction (the Z direction).

In implementations, the bonding pads BP may have the first pad widths w1_BP in the first horizontal direction (the X direction) and the second pad widths w2_BP in the second horizontal direction (the Y direction). In some implementations, the first pad width w1_BP of the bonding pads BP may be greater than half of the difference between the first width w1 and the width of the gate line contact CMC and less than half of the first width w1, and the second pad width w2_BP of the bonding pads BP may be greater than half of the difference between the second width w2 and the width of the gate line contact CMC and less than half of the second width w2.

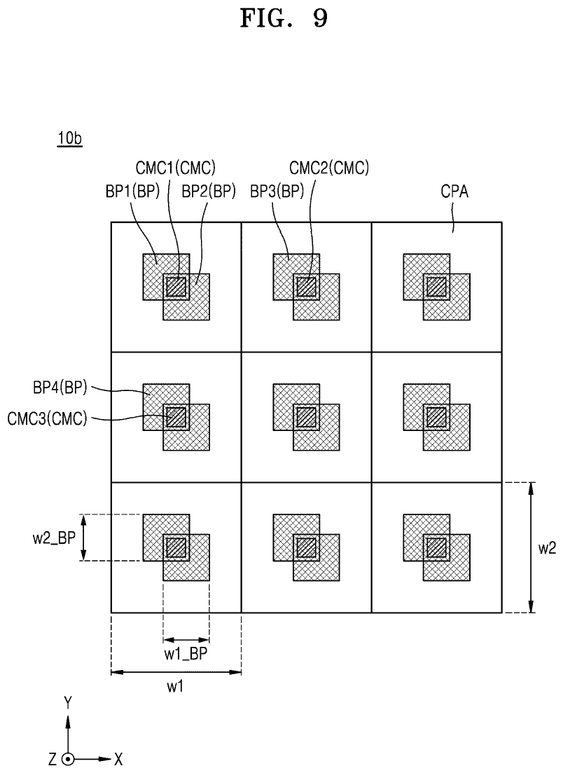

FIG. 9 is a plan view of a memory device 10b according to some implementations.

FIG. 9 shows a region corresponding to the region “EXTa” of FIG. 3.

Referring to FIG. 9, because the memory device 10b may be substantially similar to the memory device 10 described above, the difference therebetween is described in detail hereinafter.

The memory device 10a may include a plurality of bonding pads BP. The bonding pads BP may include the first bonding pad BP1, the second bonding pad BP2, the third bonding pad BP3 spaced apart from the first bonding pad BP1 in the first horizontal direction (the X direction), and the fourth bonding pad BP4 spaced apart from the first bonding pad BP1 in the second horizontal direction (the Y direction). The first bonding pad BP1 and the second bonding pad BP2 may be diagonally arranged between the first horizontal direction (the X direction) and the second horizontal direction (the Y direction). In some implementations, the first bonding pad BP1 and the second bonding pad BP2 may contact each other and may be physically and electrically connected to each other.

For example, a first bonding pad region for forming the first bonding pad BP1 may overlap a second bonding pad region for forming the second bonding pad BP2. The first bonding pad BP1 formed in the first bonding pad region may have a shape in which a portion of the first bonding pad BP1 overlaps the second bonding pad BP2. The second bonding pad BP2 formed in the second bonding pad region may have a shape in which a portion of the second bonding pad BP2 overlaps the first bonding pad BP1.

In some implementations, among the bonding pads BP that are diagonally adjacent to each other, at least one bonding pad BP may overlap a portion of the gate line contact CMC in the vertical direction (the Z direction). For example, the first bonding pad BP1 and/or the second bonding pad BP2 may overlap a portion of the first gate line contact CMC1 in the vertical direction (the Z direction).

In some implementations, among the bonding pads BP that are diagonally adjacent to each other, at least one bonding pad BP may fully overlap the gate line contact CMC in the vertical direction (the Z direction). The first bonding pad BP1 and/or the second bonding pad BP2 may overlap the entire first gate line contact CMC1 in the vertical direction (the Z direction).

In implementations, the bonding pads BP may have the first pad widths w1_BP in the first horizontal direction (the X direction) and the second pad widths w2_BP in the second horizontal direction (the Y direction). In some implementations, the first pad width w1_BP of the bonding pads BP may be less than the first width w1, and the second pad width w2_BP may be less than the second width w2. In some implementations, the first pad width w1_BP of the bonding pads BP may be greater than half of the first width w1, and the second pad width w2_BP may be greater than half of the second width w2.

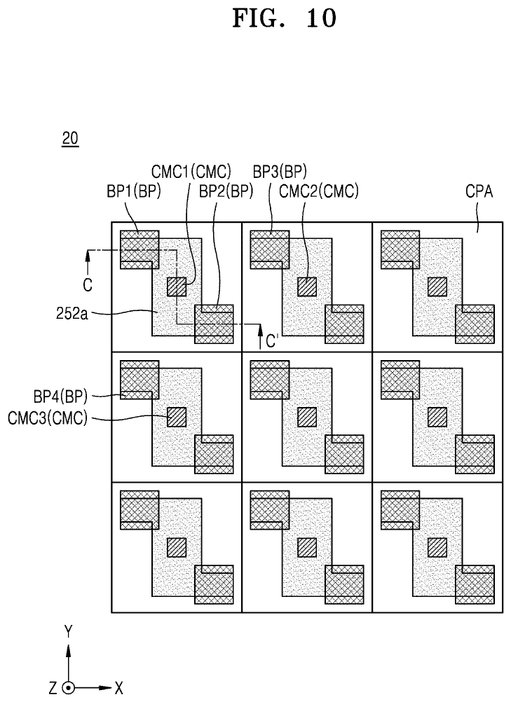

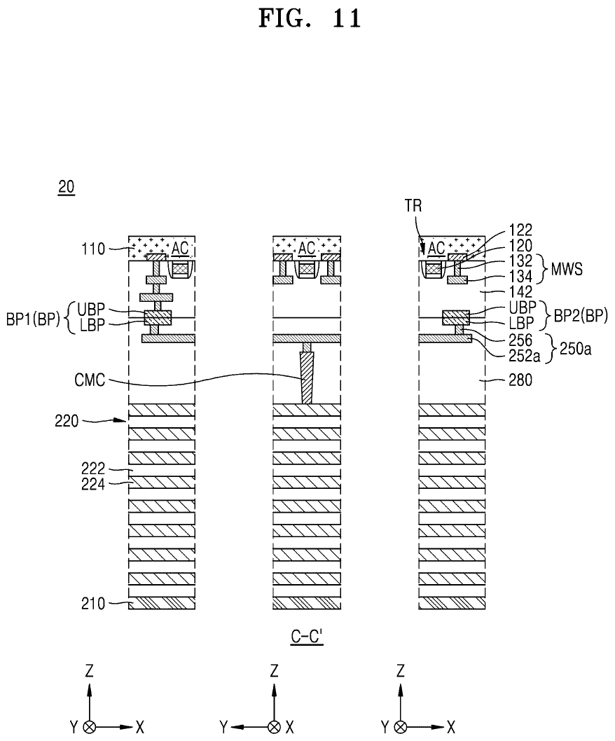

FIGS. 10 and 11 show a memory device 20 according to some implementations.

In detail, FIG. 10 is a plan view of the memory device 20 according to some implementations. FIG. 11 is a cross-sectional view of the memory device 20 of FIG. 10, taken along a line C-C′ of FIG. 10.

Referring to FIGS. 10 and 11, because the memory device 20 may be substantially similar to the memory device 10 described above, the difference therebetween is described in detail hereinafter.

As shown in FIG. 11, the memory device 20 may include a plurality of gate line contacts CMC. Each of the gate line contacts CMC may be electrically connected to a conductive wiring structure 250a and electrically connected to any one gate line selected from among a plurality of gate lines 224. An end portion of each gate line contact CMC may contact the conductive wiring structure 250a, and the other end portion thereof may contact any one gate line 224 selected from among the gate lines 224. The conductive wiring structure 250a may include a first wire layer 252a and a conductive plug 256.

As shown in FIG. 10, a portion of the first wire layer 252a may overlap at least a portion of the gate line contact CMC in the vertical direction (the Z direction). A portion of the first wire layer 252a may overlap at least a portion of the bonding pads BP in the vertical direction (the Z direction). The conductive plugs 256 may be arranged between the first wire layer 252a and the gate line contact CMC and between the first wire layer 252a and the bonding pad BP.

In some implementations, the first wire layer 252a may have a line shape extending in a zigzag form to overlap at least a portion of the gate line contact CMC and at least a portion of the bonding pads BP (e.g., a first bonding pad BP1 and a second bonding pad BP2) in the vertical direction (the Z direction). However, this is only an example, and the first wire layer 252a may have various shapes to electrically connect the bonding pads BP (e.g., the first bonding pad BP1 and the second bonding pad BP2) to the gate line contacts CMC.

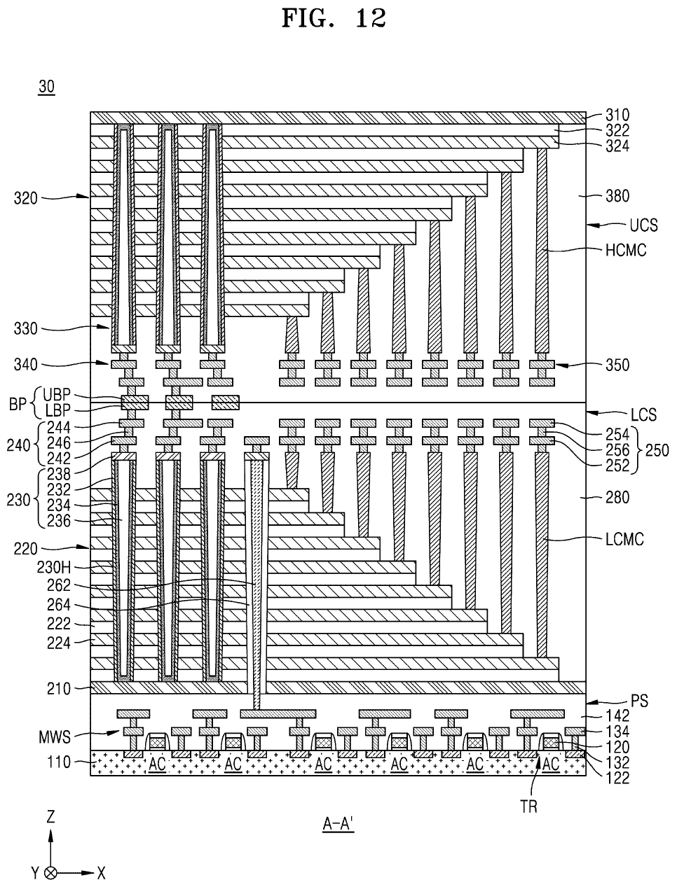

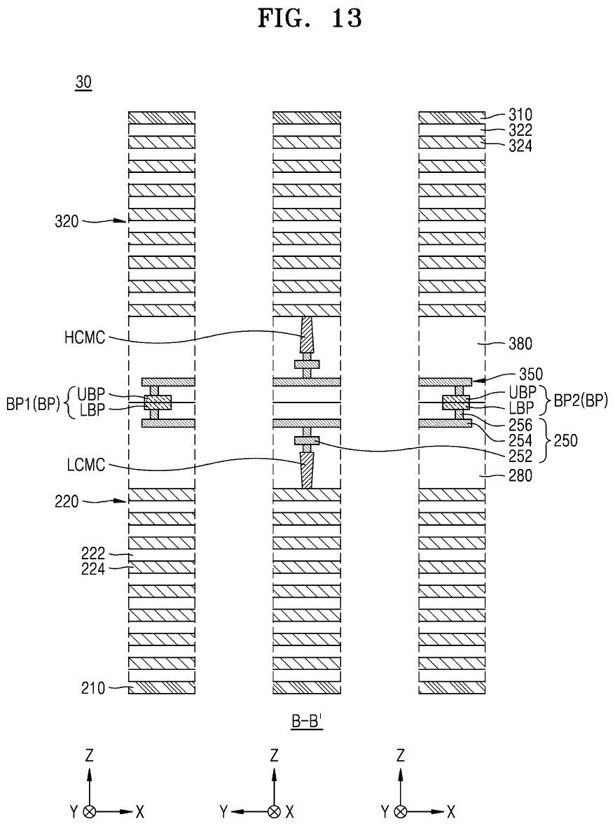

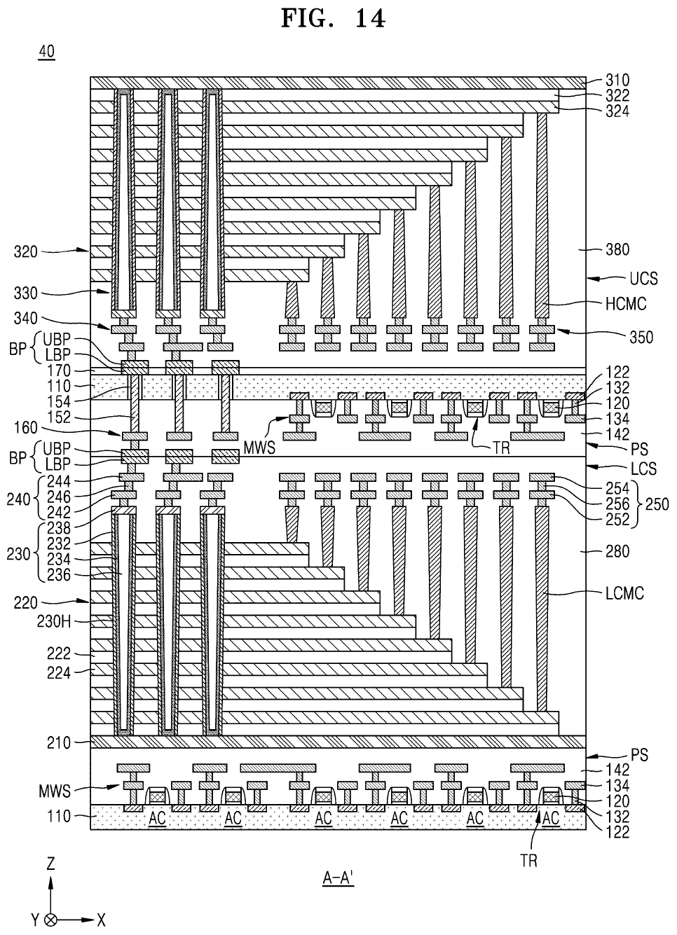

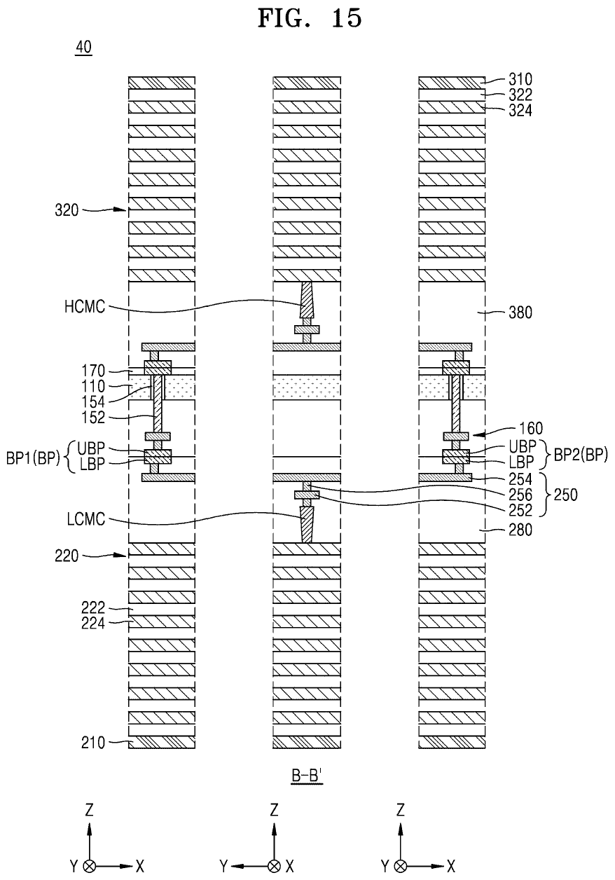

FIGS. 12 and 13 are cross-sectional views of a memory device 30 according to some implementations.

In detail, FIG. 12 may correspond to the cross-section taken along the line A-A′ of FIG. 3, and FIG. 13 may correspond to the cross-section taken along the line B-B′ of FIG. 5.

Referring to FIGS. 12 and 13, the memory device 30 may be substantially similar to the memory device 10 described above, and because the description regarding the same reference numerals is equally applied hereinafter, the repeated description is omitted.

The memory device 30 may include a peripheral circuit stack PS, a lower cell array stack LCS arranged on the peripheral circuit stack PS to overlap the same in the vertical direction (the Z direction), and an upper cell array stack UCS arranged on the lower cell array stack LCS to overlap the same in the vertical direction (the Z direction). The lower cell array stack LCS and the upper cell array stack UCS may include the memory cell array 21 described above with reference to FIG. 1, and the peripheral circuit stack PS may include the peripheral circuit 31 described above with reference to FIG. 1.

The lower cell array stack LCS may include the first substrate 210 including the cell region MCR and the connection region EXT of FIG. 3, a plurality of first interlayer insulating layers 222 and a plurality of first gate lines 224 that are alternately stacked on the first substrate 210, a plurality of first vertical channel structures 230 that extend by penetrating the first interlayer insulating layers 222 and the first gate lines 224, a plurality of lower gate line contacts LCMC respectively and electrically connected to the first gate lines 224, a first conductive wiring structure 240 that electrically connects between the first vertical channel structures 230 and the bonding pads BP, a first conductive wiring structure 250 that electrically connects between the lower gate line contacts LCMC and the bonding pads BP, and a first cell insulating layer 280.

The lower cell array stack LCS may further include a through wire plug 262 and a through wire insulating layer 264 arranged between the sidewalls of the through wire plug 262 and the first gate stack 220. The through wire plug 262 may penetrate the first substrate 210, the first gate stack 220, and the first interlayer insulating layers 222 in the vertical direction (the Z direction). The through wire plug 262 may extend into the peripheral circuit stack PS to contact a multilayer wiring structure MWS of the peripheral circuit stack PS and may be electrically connected to the multilayer wiring structure MWS of the peripheral circuit stack PS.

The upper cell array stack UCS may have a structure similar to that of the lower cell array stack LCS. The upper cell array stack UCS may include a second substrate 310 including the cell region MCR and the connection region EXT of FIG. 3, a plurality of second interlayer insulating layers 322 and a plurality of second gate lines 324 that are alternately stacked on the second substrate 310, a plurality of second vertical channel structures 320 that extend by penetrating the second interlayer insulating layers 322 and the second gate lines 324, a plurality of upper gate line contacts HCMC each electrically connected to the second gate line 324, a second conductive wiring structure 340 that electrically connects between the second vertical channel structures 330 and the bonding pads BP, a second conductive wiring structure 350 that electrically connects between the upper gate line contacts HCMC and the bonding pads BP, and a second cell insulating layer 380.

The lower cell array stack LCS may be bonded to the upper cell array stack UCS through the bonding pads BP. As shown in FIG. 13, the bonding pads BP may include a first bonding pad BP1 and a second bonding pad BP2 that are close to each other in a diagonal direction between the first horizontal direction (the X direction) and the second horizontal direction (the Y direction). The first bonding pad BP1 and the second bonding pad BP2 may be electrically connected to the same lower gate line contact LCMC and the same upper gate line contact HCMC.

The lower gate line contact LCMC may be electrically connected to any one first gate line 224 selected from among the first gate lines 224, and the upper gate line contact HCMC may be electrically connected to any one second gate line 324 selected from among the second gate lines 324.

FIGS. 14 and 15 are cross-sectional views of a memory device 40 according to some implementations.

In detail, FIG. 14 may correspond to the cross-section taken along the line A-A′ of FIG. 3, and FIG. 15 may correspond to the cross-section taken along the line B-B′ of FIG. 5.

Referring to FIGS. 14 and 15, the memory device 40 may be substantially similar to the memory device 10 described above, and because the description regarding the same reference numerals is equally applied hereinafter, the repeated description is omitted.

The memory device 40 may include a lower cell array stack LCS, a peripheral circuit stack PS arranged on the lower cell array stack LCS to overlap the same in the vertical direction (the Z direction), and an upper cell array stack UCS arranged on the peripheral circuit stack PS to overlap the same in the vertical direction (the Z direction). The peripheral circuit stack PS may be arranged between the lower cell array stack LCS and the upper cell array stack UCS. The lower cell array stack LCS and the upper cell array stack UCS may include the memory cell array 21 described above with reference to FIG. 1, and the peripheral circuit stack PS may include the peripheral circuit 31 described above with reference to FIG. 1.

The lower cell array stack LCS may include the first substrate 210 including the cell region MCR and the connection region EXT of FIG. 3, a plurality of first interlayer insulating layers 222 and a plurality of first gate lines 224 that are alternately stacked on the first substrate 210, a plurality of first vertical channel structures 230 that extend by penetrating the first interlayer insulating layers 222 and the first gate lines 224, a plurality of lower gate line contacts LCMC each electrically connected to the first gate line 224, a first conductive wiring structure 240 that electrically connects between the first vertical channel structures 230 and the bonding pads BP, a first conductive wiring structure 250 that electrically connects between the lower gate line contacts LCMC and the bonding pads BP, and a first cell insulating layer 280.

The peripheral circuit stack PS may further include a peripheral circuit through plug 152 penetrating the peripheral circuit substrate 110, a peripheral circuit insulating spacer 154 located between the peripheral circuit through plug 152 and the peripheral circuit substrate 110, a peripheral circuit wiring structure 160 configured to electrically connect between the peripheral circuit through plug 152 and the bonding pads BP, and a peripheral circuit bonding insulating layer 170 surrounding a lower bonding metal pad LBP on the upper surface of the peripheral circuit stack PS. The peripheral circuit through plug 152 may penetrate the peripheral circuit substrate 110 and extend into the peripheral circuit insulating layer 142. The peripheral circuit insulating spacer 154 may insulate between the peripheral circuit through plug 152 and the peripheral circuit substrate 110.

The upper cell array stack UCS may have a structure similar to that of the lower cell array stack LCS. The upper cell array stack UCS may include a second substrate 310 including the cell region MCR and the connection region EXT of FIG. 3, a plurality of second interlayer insulating layers 322 and a plurality of second gate lines 324 that are alternately stacked on the second substrate 310, a plurality of second vertical channel structures 320 that extend by penetrating the second interlayer insulating layers 322 and the second gate lines 324, a plurality of upper gate line contacts HCMC each electrically connected to the second gate line 324, a second conductive wiring structure 340 that electrically connects between the second vertical channel structures 330 and the bonding pads BP, a second conductive wiring structure 350 that electrically connects between the upper gate line contacts HCMC and the bonding pads BP, and a second cell insulating layer 380.

The lower cell array stack LCS and the peripheral circuit stack PS may be bonded to the upper cell array stack UCS and the peripheral circuit stack PS through the bonding pads BP. As shown in FIG. 15, the bonding pads BP may include a first bonding pad BP1 and a second bonding pad BP2 that are close to each other in a diagonal direction between the first horizontal direction (the X direction) and the second horizontal direction (the Y direction). The first bonding pad BP1 may be provided in plurality and may be respectively arranged on the lower surface and the upper surface of the peripheral circuit stack PS. The second bonding pad BP2 may be provided in plurality and may be respectively arranged on the lower surface and the upper surface of the peripheral circuit stack PS. The first bonding pads BP1 and the second bonding pads BP2 may be electrically connected to the same lower gate line contact LCMC and the same upper gate line contact HCMC.

The lower gate line contact LCMC may be electrically connected to any one first gate line 224 selected from among the first gate lines 224, and the upper gate line contact HCMC may be electrically connected to any one second gate line 324 selected from among the second gate lines 324.

The first bonding pads BP1 may be electrically connected to the second bonding pads BP2 through the peripheral circuit through plug 152 and the peripheral circuit wiring structure 160 included in the peripheral circuit stack PS.

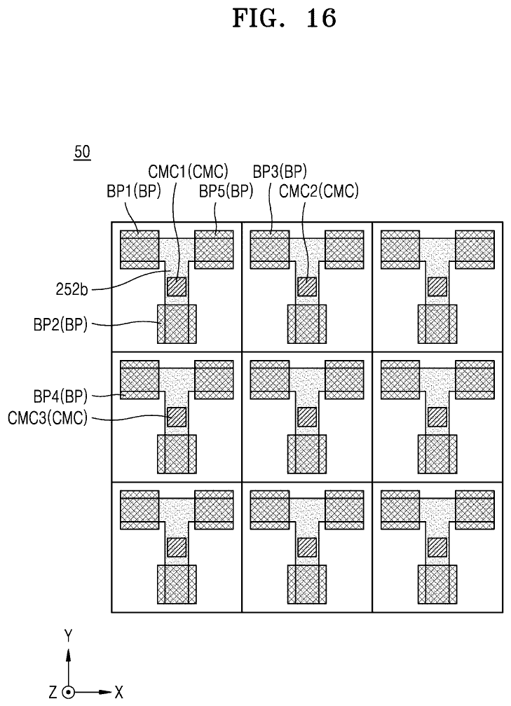

FIG. 16 is a plan view of a memory device 50 according to some implementations.

FIG. 16 shows a region corresponding to the region “EXTa” of FIG. 3.

Referring to FIG. 16, because the memory device 50 may be substantially similar to the memory device 10 described above, the difference therebetween is specifically described hereinafter.

The memory device 50 may include a plurality of bonding pads BP. The bonding pads BP may include a first bonding pad BP1, a second bonding pad BP2, a third bonding pad BP3 spaced apart from the first bonding pad BP1 in the first horizontal direction (the X direction), a fourth bonding pad BP4 spaced apart from the first bonding pad BP1 in the second horizontal direction (the Y direction), and a fifth bonding pad BP5 spaced apart from the first bonding pad BP1 in the first horizontal direction (the X direction) and located between the first bonding pad BP1 and the third bonding pad BP3. The first bonding pad BP1 and the second bonding pad BP2 may be diagonally arranged between the first horizontal direction (the X direction) and the second horizontal direction (the Y direction).

The first bonding pad BP1, the second bonding pad BP2, and the fifth bonding pad BP5 may be electrically connected to the first gate line contact CMC1. In detail, the first bonding pad BP1, the second bonding pad BP2, and the fifth bonding pad BP5 may be electrically connected to a first wire layer 252b through conductive plugs under the first bonding pad BP1, the second bonding pad BP2, and the fifth bonding pad BP5 and may be electrically connected to the first gate line contact CMC1 through a conductive plug under the first wire layer 252b. The third bonding pad BP3 may be electrically connected to the second gate line contact CMC2 that is different from the first gate line contact CMC1, and the fourth bonding pad BP4 may be electrically connected to the third gate line contact CMC2 that is different from the first gate line contact CMC1.

As shown in FIG. 16, the memory device 50 may include the first wire layer 252b. A portion of the first wire layer 252b may overlap at least a portion of the gate line contact CMC in the vertical direction (the Z direction). A portion of the first wire layer 252b may overlap at least a portion of the bonding pads BP in the vertical direction (the Z direction). It is illustrated that the memory device 50 includes a single first wire layer 252b, but it is merely an example. The memory device 50 may include multiple wire layers located at different vertical levels.

In some implementations, the first wire layer 252b may have a line shape extending in a T shape to overlap at least a portion of the gate line contact CMC and at least a portion of the bonding pads BP (e.g., the first bonding pad BP1, the second bonding pad BP2, and the fifth bonding pad BP5) in the vertical direction (the Z direction). However, this is only an example, and the first wire layer 252b may have various shapes to electrically connect the bonding pads BP (e.g., the first bonding pad BP1 and the second bonding pad BP2) to the gate line contacts CMC.

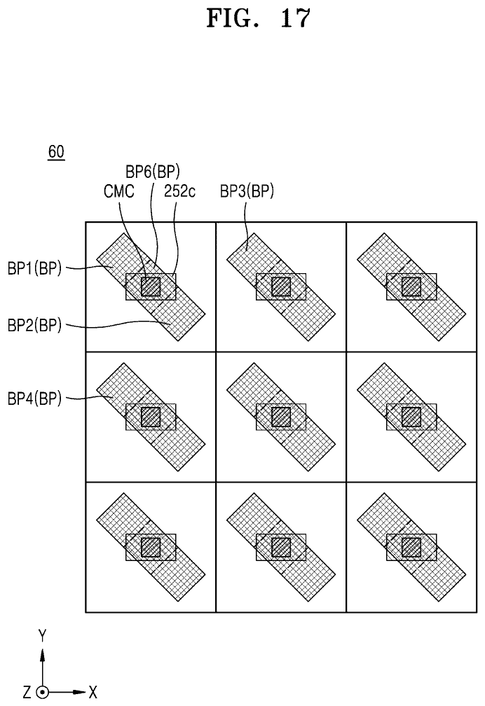

FIG. 17 is a plan view of a memory device 60 according to some implementations.

FIG. 17 shows a region corresponding to the region “EXTa” of FIG. 3.

Referring to FIG. 17, because the memory device 60 may be substantially similar to the memory device 10 described above, the difference therebetween is specifically described hereinafter.

The memory device 60 may include a plurality of bonding pads BP. The bonding pads BP may include a first bonding pad BP1, a second bonding pad BP2, a third bonding pad BP3 spaced apart from the first bonding pad BP1 in the first horizontal direction (the X direction), a fourth bonding pad BP4 spaced apart from the first bonding pad BP1 in the second horizontal direction (the Y direction), and a sixth bonding pad BP6 located between the first bonding pad BP1 and the second bonding pad BP2 and contacting each of the first bonding pad BP1 and the second bonding pad BP2. The first bonding pad BP1 and the second bonding pad BP2 may be arranged diagonally between the first horizontal direction (the X direction) and the second horizontal direction (the Y direction).

The first bonding pad BP1, the second bonding pad BP2, and the sixth bonding pad BP6 may be combined with each other as a single bonding pad. The first bonding pad BP1, the second bonding pad BP2, and the sixth bonding pad BP6, which are integrally formed as a single bonding pad, may be electrically connected to the first gate line contact CMC1. In detail, the first bonding pad BP1, the second bonding pad BP2, and the sixth bonding pad BP6, which are integrally formed, may be electrically connected to a first wire layer 252c through conductive plugs under the first bonding pad BP1, the second bonding pad BP2, and the sixth bonding pad BP6 and may be electrically connected to the first gate line contact CMC1 through a conductive plug under the first wire layer 252c. The third bonding pad BP3 may be electrically connected to the second gate line contact CMC2 that is different from the first gate line contact CMC1, and the fourth bonding pad BP4 may be electrically connected to the third gate line contact CMC3 that is different from the first gate line contact CMC1.

As shown in FIG. 17, the first bonding pad BP1, the second bonding pad BP2, and the sixth bonding pad BP6, which are integrally formed, may have a bar shape, for example, a bar shape extending in a diagonal direction between the first horizontal direction (the X direction) and the second horizontal direction (the Y direction).

As shown in FIG. 17, the memory device 60 may include the first wire layer 252c. The first wire layer 252c may overlap at least a portion of the gate line contact CMC in the vertical direction (the Z direction). The first wire layer 252c may overlap at least a portion of the bonding pads BP in the vertical direction (the Z direction). It is illustrated that the memory device 60 includes a single first wire layer 252c, but it is merely an example. The memory device 60 may include multiple wire layers located at different vertical levels.

In some implementations, the first wire layer 252c may have an island shape overlapping, in the vertical direction (the Z direction), at least a portion of the gate line contact CMC and at least a portion of the bonding pads BP (e.g., the first bonding pad BP1, the second bonding pad BP2, and the sixth bonding pad BP6). However, this is only an example, and the first wire layer 252c may have various shapes to electrically connect the bonding pads BP (e.g., the first bonding pad BP1, the second bonding pad BP2, and the sixth bonding pad BP6) to the gate line contacts CMC.

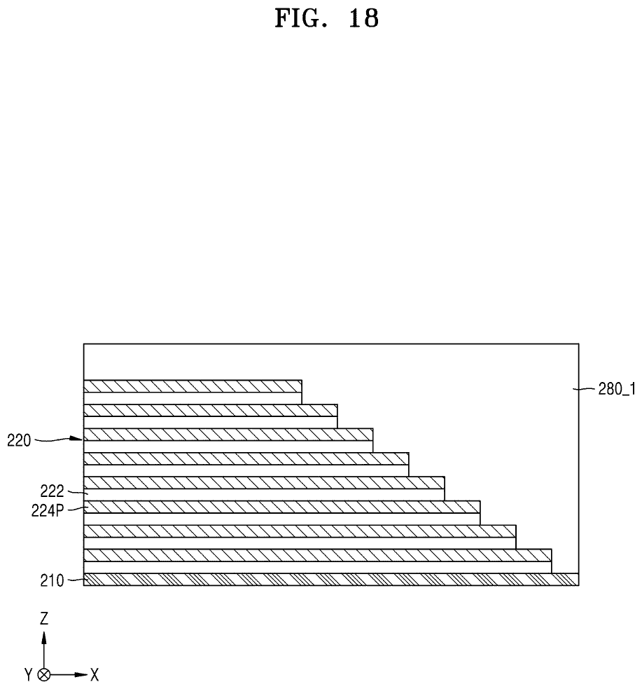

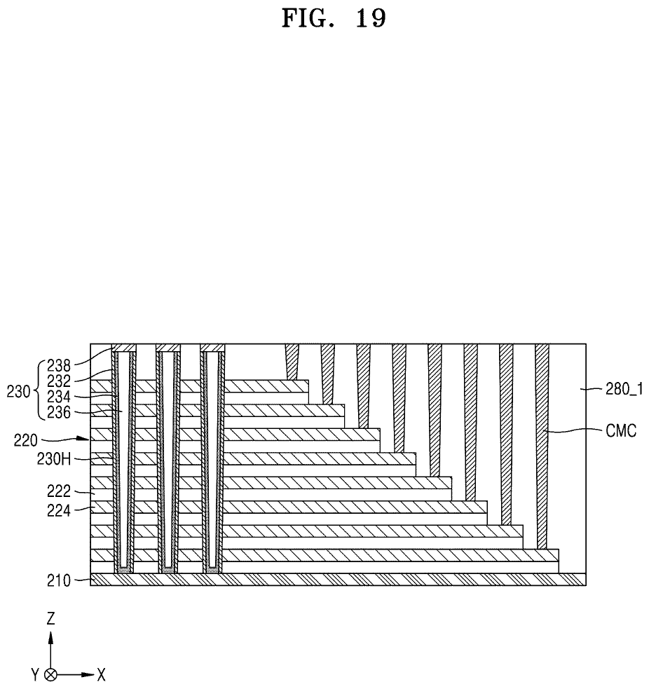

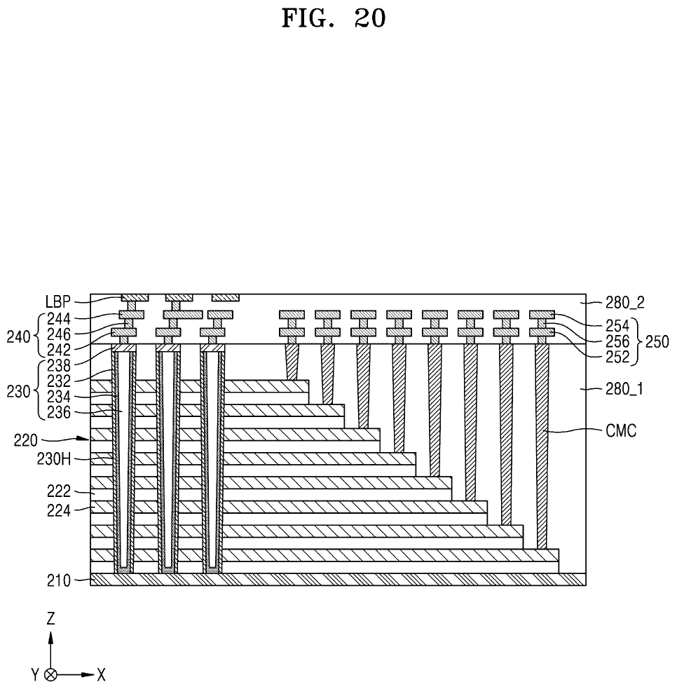

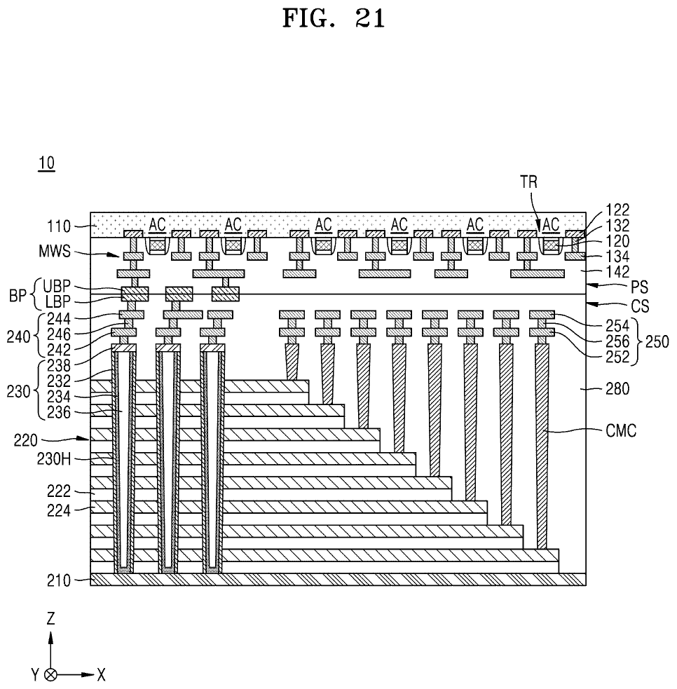

FIGS. 18 and 21 are cross-sectional views sequentially showing a method of manufacturing the memory device 10 in a process order, according to some implementations.

Referring to FIG. 18, a plurality of interlayer insulating layers 222 and a plurality of sacrificial layers 224P may be alternately stacked on the substrate 210. The interlayer insulating layers 222 and the sacrificial layers 224P may be partially removed to make the sacrificial layers 224P extend to different lengths in the first horizontal direction (the X direction). As the interlayer insulating layers 222 and the sacrificial layers 224P are partially removed, portions of the upper surfaces of the sacrificial layers 224P may be exposed, and end portions of respective sacrificial layers 224P may form a staircase shape. To partially remove the interlayer insulating layers 222 and the sacrificial layers 224P, a photolithography process and an etching process may be repeatedly performed on the interlayer insulating layers 222 and the sacrificial layers 224P. Then, a lower cell insulating layer 280_1 covering the end portion of each sacrificial layer 224P may be formed.

The sacrificial layers 224P may be replaced with the gate lines (224 of FIG. 19) through a subsequent process. The sacrificial layers 224P may include a material with etch selectivity relative to the interlayer insulating layers 222. For example, the sacrificial layer 224P may each include a material selected from among silicon, silicon oxide, silicon carbide, and silicon nitride and may include a material different from that of the interlayer insulating layers 222.

Referring to FIG. 19, a plurality of vertical channel structures 230 penetrating the interlayer insulating layers 222 and the sacrificial layers 224P may be formed. To form the vertical channel structures 230, the interlayer insulating layers 222 and the sacrificial layers 224P may be anisotropically etched, thus forming channel holes 230H penetrating the interlayer insulating layers 222 and the sacrificial layers 224P. In some implementations, a portion of the substrate 210 may be exposed at the bottom of the channel hole 230H.

Then, a gate dielectric layer 232 conformally covering the sidewalls of the channel hole 230H may be formed in the channel hole 230H, a channel layer 234 conformally covering the sidewalls of the gate dielectric layer 232 may be formed on the gate dielectric layer 232, and a buried insulating layer 236 filling the remaining space in the channel hole 230H may be formed on the channel layer 234. Accordingly, the vertical channel structure 230 may be formed.

Then, the sacrificial layers (224P of FIG. 18) may be removed, and the gate lines 224 may be formed. Openings penetrating the interlayer insulating layers 222 and the sacrificial layers (224P of FIG. 18) may be formed to remove the sacrificial layers (224P of FIG. 18), and the sacrificial layers (224P of FIG. 18) may be removed through the openings. For example, the opening may be a trench-shaped opening for forming the word line cut structure WLC of FIG. 3. The sacrificial layers (224P of FIG. 18) may be selectively removed with respect to the interlayer insulating layers 222 through, for example, wet etching.

The gate lines 224 may be formed by including conductive materials in regions where the sacrificial layers (224P of FIG. 18) are removed. For example, the gate line 224 may include metal, polycrystalline silicon, or a metal silicide material.

Then, the gate line contacts CMC connected to the end portions of respective gate lines 224 may be formed. To form the gate line contacts CMC, a contact hole may be formed by anisotropically etching the lower cell insulating layer 280_1, and a conductive material may be included in the contact hole. A portion of the gate line 224 may be exposed through the bottom of each contact hole.

Referring to FIG. 20, the conductive wiring structures 240 may be formed on the vertical channel structures 230, and the conductive wiring structures 250 may be formed on the gate line contacts CMC. A plurality of lower bonding metal pads LBP may be formed on the conductive wiring structures 240 and 250. To form the conductive wiring structures 240 and 250 and the lower bonding metal pads LBP, processes where an insulating layer 280_2 is formed on the upper surface of the lower cell insulating layer 280_1, a plurality of local regions of the insulating layer 280_2 are removed, and a conductive material is deposited in the local regions may be repeated.

Referring to FIG. 21, the peripheral circuit stack PS may be aligned on the cell array stack CS, which is a result of FIG. 20, to enable the lower bonding metal pads LBP of the cell array stack CS to face the upper bonding metal pads UBP of the peripheral circuit stack PS, and the lower bonding metal pads LBP may be bonded to the upper bonding metal pads UBP.

In some implementations, the lower bonding metal pads LBP may be directly bonded to the upper bonding metal pads UBP without a separate adhesive layer by pressing the peripheral circuit stack PS towards the cell array stack CS. In some implementations, before the lower bonding metal pads LBP are bonded to the upper bonding metal pads UBP, the exposed surfaces of the lower bonding metal pads LBP and the upper bonding metal pads UBP may undergo surface treatment using hydrogen plasma to increase adhesion between the lower bonding metal pads LBP are bonded to the upper bonding metal pads UBP. The lower bonding metal pads LBP and the upper bonding metal pads UBP may each include copper, aluminum, or tungsten, but one or more implementations are not limited thereto.

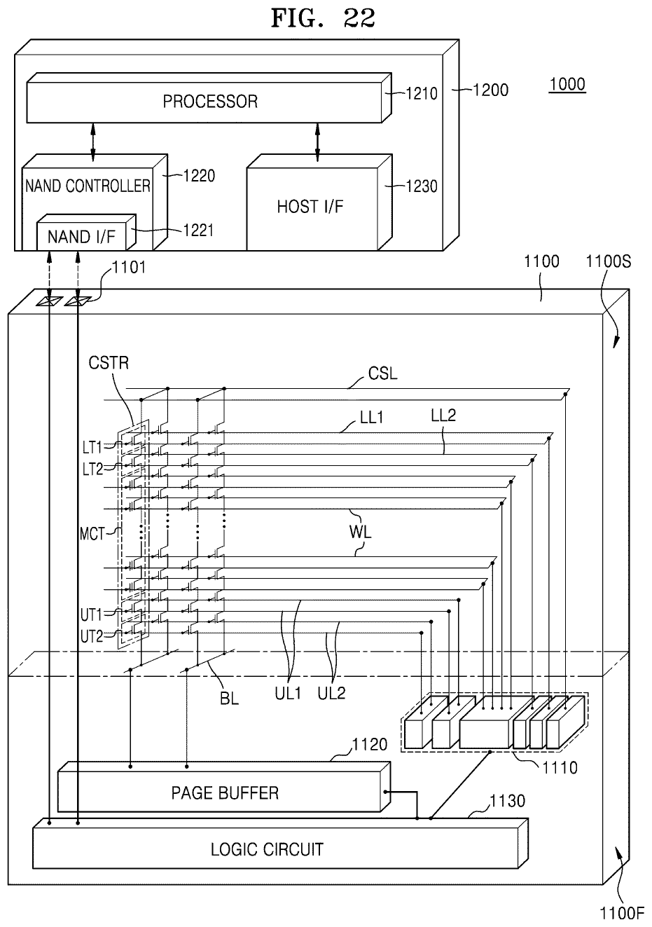

FIG. 22 schematically shows a data storage system 1000 including a memory device, according to some implementations.

Referring to FIG. 22, the data storage system 1000 may include one or more memory devices 1100 and a memory controller 1200 electrically connected to the memory devices 1100. The data storage system 1000 may be, for example, a solid-state drive (SSD) device, a universal serial bus (USB), a computing system, a medical device, or a communication device, all of which include at least one memory device 1100.

The memory device 1100 may be a non-volatile semiconductor device, and for example, the memory device 1100 may be a NAND flash semiconductor device including one of the memory devices 10 to 60 described above.

The memory device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure that includes a bit line BL, a common source line CSL, a plurality of word lines WL, a first string selection line UL1, a second string selection line UL2, a first ground selection line LL1, a second ground selection line LL2, and a plurality of memory cell strings CSTR located between the bit line BL and the common source line CSL.

In the second structure 1100S, each memory cell string CSTR may include ground selection transistors LT1 and LT2 that are adjacent to the common source line CSL, string selection transistors UT1 and UT2 that are adjacent to the bit line BL, and memory cell transistors MCT that are arranged between the ground selection transistors LT1 and LT2 and the string selection transistors UT1 and UT2. The number of ground selection transistors LT1 and LT2 and the number of string selection transistors UT1 and UT2 may vary according to some implementations.

In some implementations, the ground selection lines LL1 and LL2 may be connected to the gate electrodes of the ground selection transistors LT1 and LT2, respectively. The word line WL may be connected to the gate electrode of the memory cell transistor MCT. The string selection lines UL1 and UL2 may be connected to the gate electrodes of the string selection transistors UT1 and UT2, respectively.

The common source line CSL, the ground selection lines LL1 and LL2, the word lines WL, and the string selection lines UL1 and UL2 may be connected to the row decoder 1110. The bit lines BL may be electrically connected to the page buffer 1120.

The memory device 1100 may communicate with the memory controller 1200 through an input/output pad 1101 that is electrically connected to the logic circuit 1130. The input/output pad 1101 may be electrically connected to the logic circuit 1130.

The memory controller 1200 may include a processor 1210, a NAND controller 1220, and a host interface 1230. In some implementations, the data storage system 1000 may include a plurality of memory devices 1100, and in this case, the memory controller 1200 may control the memory devices 1100.

The processor 1210 may control the overall operations of the memory system 1000 including the memory controller 1200. The processor 1210 may operate according to specific firmware and control the NAND controller 1220 to access the memory device 1100. The NAND controller 1220 may include a NAND interface 1221 processing communication with the memory device 1100. Through the NAND interface 1221, a control command for controlling the memory device 1100, data to be written on the memory cell transistors MCT of the memory device 1100, data to be read from the memory cell transistors MCT of the memory device 1100, and the like may be transmitted. The host interface 1230 may provide a communication function between the data storage system 1000 and an external host. When receiving a control command from an external host through the host interface 1230, the processor 1210 may control the memory device 1100 in response to the control command.

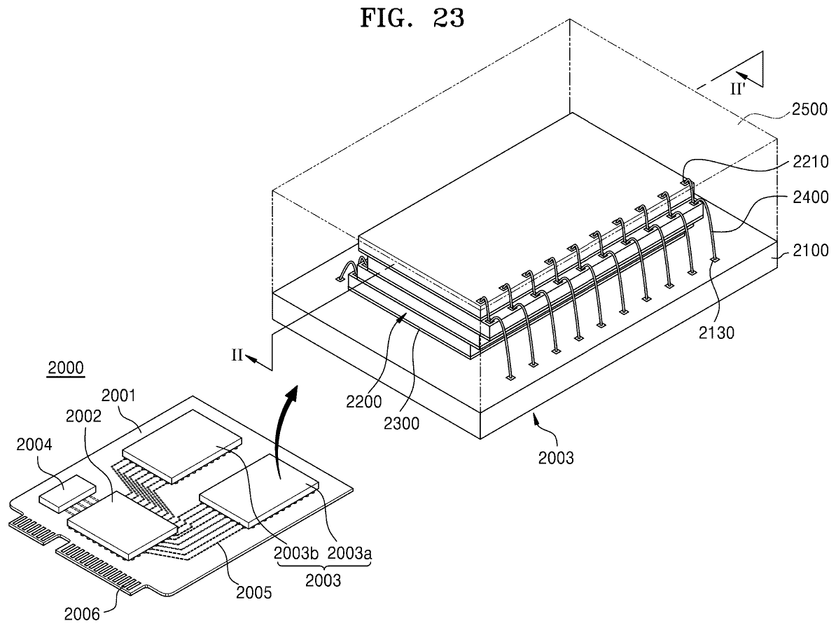

FIG. 23 is a schematic perspective view of a data storage system 2000 including a semiconductor device, according to some implementations.

Referring to FIG. 23, the data storage system 2000 according to some implementations may include a main substrate 2001, a memory controller 2002 mounted on the main substrate 2001, one or more semiconductor packages 2003, and dynamic random access memory (DRAM) 2004.

The semiconductor package 2003 and the DRAM 2004 may be connected to the memory controller 2002 by a plurality of wire patterns 2005 formed on the main substrate 2001.

The main substrate 2001 may include a connector 2006 including a plurality of pins coupled to the external host. The number and arrangements of pins in the connector 2006 may differ according to the communication interface between the data storage system 2000 and the external host. In some implementations, the data storage system 2000 may communicate with the external host according to any one of interfaces, for example, USB, Peripheral Component Interconnect Express (PCI-Express), Serial Advanced Technology Attachment (SATA), and M-Phy for Universal Flash Storage (UFS). In some implementations, the data storage system 2000 may operate by the power supplied from the external host through the connector 2006. The data storage system 2000 may further include a power management integrated circuit (PMIC) configured to distribute the power from the external host to the memory controller 2002 and the semiconductor package 2003.

The memory controller 2002 may write data to the semiconductor package 2003 or read data therefrom and may improve the operation speed of the data storage system 2000.

The DRAM 2004 may be a buffer memory for reducing a speed gap between the external host and the semiconductor package 2003 that is a data storage space. The DRAM 2004 included in the data storage system 2000 may also function as a cache memory and provide a space for temporarily storing data during a control operation performed on the semiconductor package 2003. When the data storage system 2000 includes the DRAM 2004, the memory controller 2002 may further include a DRAM controller to control the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, a plurality of semiconductor chips 2200 on the package substrate 2100, an adhesive layer 2300 arranged on a lower surface of each semiconductor chip 2200, a connection structure 2400 configured to electrically connect the semiconductor chips 2200 to the package substrate 2100, and a molding layer 2500 covering, on the package substrate 2100, the semiconductor chips 2200 and the connection structure 2400.

The package substrate 2100 may be a printed circuit board including a plurality of package upper pads 2130. Each semiconductor chip 2200 may include an input/output pad 2210. The input/output pad 2210 may correspond to the input/output pad 1101 of FIG. 22. Each semiconductor chip 2200 may include at least one of the memory devices 10 to 60 described above.

In implementations, the connection structure 2400 may be a bonding wire configured to electrically connect the input/output pad 2210 to a package upper pad 2130. Therefore, in the first semiconductor package 2003a and the second semiconductor package 2003b, the semiconductor chips 2200 may be electrically connected to each other in a bonding wire manner and electrically connected to the package upper pad 2130 of the package substrate 2100. In some implementations, in the first semiconductor package 2003a and the second semiconductor package 2003b, the semiconductor chips 2200 may be electrically connected to each other through a connection structure including a through silicon via (TSV), instead of the connection structure 2400 that is the bonding wire.

In some implementations, the memory controller 2002 and the semiconductor chips 2200 may be included in one package. In some implementations, the memory controller 2002 and the semiconductor chips 2200 may be mounted on an interposer substrate that is different from the main substrate 2001 and may be connected to each other by a wire formed on the interposer substrate.

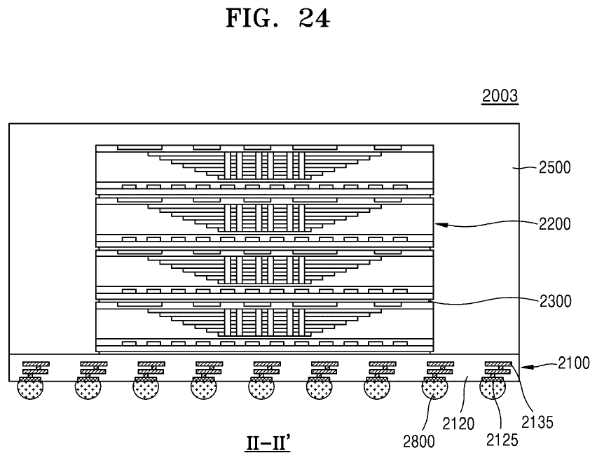

FIG. 24 is a schematic cross-sectional view of semiconductor packages 2003 according to some implementations. FIG. 24 is a cross-sectional view of the semiconductor packages 2003, taken along a line II-II′ of FIG. 23.

Referring to FIG. 24, in the semiconductor package 2003, a package substrate 2100 may be a printed circuit board. The package substrate 2100 may include a package substrate body portion 2120, a plurality of package upper pads (2130, see FIG. 23) on the upper surface of the package substrate body portion 2120, a plurality of lower pads 2125 arranged on or exposed through the lower surface of the package substrate body portion 2120, and a plurality of internal wires 2135 electrically connecting the package upper pads (2130, see FIG. 23) to the lower pads 2125 within the package substrate body portion 2120. As shown in FIG. 24, the package upper pads 2130 may be electrically connected to the connection structures 2400. As shown in FIG. 24, the lower pads 2125 may be connected to the wiring patterns 2005 on the main substrate 2001 of the data storage system 2000 of FIG. 23 through a plurality of conductive bumps 2800. Each semiconductor chip 2200 may include at least one of the memory devices 10 to 60 described above.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the semiconductor device has been particularly shown and described with reference to implementations thereof, it will be understood that various changes in form and details may be made therein without departing from the spirit and scope of the following claims.

What is claimed is:

1. A memory device comprising:
a substrate;
a gate stack comprising a plurality of gate lines stacked on the substrate in a vertical direction and extending in a first horizontal direction;
a gate line contact electrically connected to a gate line of the plurality of gate lines;
a conductive wiring structure electrically connected to the gate line contact; and
a plurality of bonding pads arranged on the conductive wiring structure,
wherein the plurality of bonding pads comprise:
a first bonding pad;
a second bonding pad;
a third bonding pad spaced apart from the first bonding pad in the first horizontal direction; and
a fourth bonding pad spaced apart from the first bonding pad in a second horizontal direction that is perpendicular to the first horizontal direction,
wherein the conductive wiring structure electrically connects the first bonding pad and the second bonding pad to the gate line contact, and
wherein the first bonding pad and the second bonding pad are arranged in a diagonal direction with respect to each other, the diagonal direction being defined between the first horizontal direction and the second horizontal direction.

2. The memory device of claim 1, wherein the second bonding pad is spaced apart from the first bonding pad along the diagonal direction.

3. The memory device of claim 1, wherein the first bonding pad and the second bonding pad are in contact with each other.

4. The memory device of claim 1, wherein the gate line contact includes a plurality of gate line contacts,
wherein the plurality of gate line contacts comprise a first gate line contact, a second gate line contact, and a third gate line contact,
wherein the second gate line contact is arranged apart from the first gate line contact in the first horizontal direction,
wherein the third gate line contact is arranged apart from the first gate line contact in the second horizontal direction,
wherein the first bonding pad and the second bonding pad are electrically connected to the first gate line contact,
wherein the third bonding pad is electrically connected to the second gate line contact, and
wherein the fourth bonding pad is electrically connected to the third gate line contact.

5. The memory device of claim 1, wherein a first distance is defined from a center of the first bonding pad to a center of the second bonding pad, a second distance is defined from the center of the first bonding pad to a center of the third bonding pad, and a third distance is defined from the center of the first bonding pad to a center of the fourth bonding pad are defined, and
wherein the first distance is less than or equal to the second distance and the third distance.

6. The memory device of claim 1, wherein the conductive wiring structure overlaps each of the first bonding pad and the second bonding pad in the vertical direction and overlaps the gate line contact in the vertical direction.

7. The memory device of claim 1, wherein the conductive wiring structure comprises:
a wire layer located at a different vertical level from the gate line contact; and
a conductive plug electrically connecting the gate line contact and the wire layer to each other.

8. The memory device of claim 1, wherein the conductive wiring structure comprises:
a first wire layer located at a different vertical level from the gate line contact;
a second wire layer located at a different vertical level from the vertical level of the first wire layer; and
a conductive plug electrically connecting the gate line contact with the first wire layer and connecting the first wire layer with the second wire layer.

9. The memory device of claim 1, wherein the substrate comprises:
a connection region in which the gate line contact is connected to a gate line of the plurality of gate lines; and
a cell region adjacent to the connection region,
wherein the connection region comprises a plurality of contact regions,
wherein the gate line contact, the first bonding pad, and the second bonding pad are arranged in a contact region of the plurality of contact regions,
wherein the contact region has a first width in the first horizontal direction and a second width in the second horizontal direction, and
wherein a horizontal width of each of the first bonding pad and the second bonding pad is less than each of the first width and the second width.

10. The memory device of claim 1, further comprising a fifth bonding pad arranged between the first bonding pad and the third bonding pad and spaced apart from the first bonding pad and the third bonding pad,
wherein the fifth bonding pad is electrically connected to the gate line contact through the conductive wiring structure.

11. The memory device of claim 1, wherein the second bonding pad is spaced apart from the first bonding pad along the diagonal direction, and
wherein the memory device further comprises a sixth bonding pad disposed between the first bonding pad and the second bonding pad and connecting the first bonding pad with the second bonding pad.

12. A memory device comprising:
a first gate stack comprising a plurality of first gate lines that are stacked in a vertical direction and extend in a first horizontal direction;
a lower cell array stack comprising a lower gate line contact electrically connected to a first gate line of the plurality of first gate lines; and
a plurality of bonding pads arranged on the lower cell array stack,
wherein the plurality of bonding pads comprise:
a first bonding pad;
a second bonding pad;
a third bonding pad spaced apart from the first bonding pad in the first horizontal direction; and
a fourth bonding pad spaced apart from the first bonding pad in a second horizontal direction that is perpendicular to the first horizontal direction,
wherein the first bonding pad and the second bonding pad are electrically connected to the lower gate line contact,
wherein a first distance is defined from a center of the first bonding pad to a center of the second bonding pad, a second distance is defined from the center of the first bonding pad to a center of the third bonding pad, and a third distance is defined from the center of the first bonding pad to a center of the fourth bonding pad, and
wherein the first distance is less than or equal to the second distance and the third distance.

13. The memory device of claim 12, further comprising a peripheral circuit stack comprising a circuit substrate and a plurality of circuits arranged on the circuit substrate,
wherein the peripheral circuit stack is bonded to the lower cell array stack through the plurality of bonding pads.

14. The memory device of claim 12, further comprising a second gate stack comprising a plurality of second gate lines that are stacked in the vertical direction and extend in the first horizontal direction; and
an upper cell array stack comprising a second gate line contact that electrically connects to a second gate line of the plurality of second gate lines,
wherein the upper cell array stack is bonded to the lower cell array stack through the plurality of bonding pads.

15. The memory device of claim 12, wherein the first bonding pad and the second bonding pad do not overlap the lower gate line contact in the vertical direction.

16. The memory device of claim 12, wherein the second bonding pad is spaced apart from the first bonding pad along a diagonal direction with respect to each other, the diagonal direction being defined between the first horizontal direction and the second horizontal direction, and
a portion of each of the first bonding pad and the second bonding pad overlap the lower gate line contact in the vertical direction.

17. The memory device of claim 12, wherein the first bonding pad and the second bonding pad are in contact with each other, and
a portion of each of the first bonding pad and the second bonding pad overlap the lower gate line contact in the vertical direction.

18. A memory device comprising:
a substrate comprising a cell region and a connection region;
a gate stack comprising a plurality of gate lines stacked on the substrate in a vertical direction and extending in a first horizontal direction;
a vertical channel structure penetrating the gate stack in the cell region;
a bit line electrically connected to the vertical channel structure;
a gate line contact electrically connected to a gate line of the plurality of gate lines in the connection region;
a conductive wiring structure electrically connected to the gate line contact; and
a plurality of bonding pads arranged on the conductive wiring structure,
wherein the plurality of bonding pads comprise:
a first bonding pad electrically connected to the gate line contact;
a second bonding pad electrically connected to the gate line contact;
a third bonding pad spaced apart from the first bonding pad in the first horizontal direction; and
a fourth bonding pad spaced apart from the first bonding pad in a second horizontal direction that is perpendicular to the first horizontal direction,
wherein a first distance is defined from a center of the first bonding pad to a center of the second bonding pad, a second distance is defined from the center of the first bonding pad to a center of the third bonding pad, and a third distance is defined from the center of the first bonding pad to a center of the fourth bonding pad, and
wherein the first distance is less than or equal to the second distance and the third distance.

19. The memory device of claim 18, wherein the conductive wiring structure comprises:
a wire layer located at a same vertical level as the bit line; and
a conductive plug electrically connecting the wire layer and the gate line contact to each other.

20. The memory device of claim 18, further comprising a fifth bonding pad arranged between the first bonding pad and the third bonding pad and spaced apart from the first bonding pad and the third bonding pad,
wherein the fifth bonding pad is electrically connected to the gate line contact through the conductive wiring structure.
